(19) United States
(12) Patent Application Publication
(10) Pub. No.: US 2025/0309064 A1
(43) Pub. Date: Oct. 2, 2025

(54) SEMICONDUCTOR DEVICE AND METHOD OF MANUFACTURING THE SAME

(71) Applicant: Renesas Electronics Corporation, Tokyo (JP)

(72) Inventor: Youichi ABE, Tokyo (JP)

(21) Appl. No.: 19/071,979

(22) Filed: Mar. 6, 2025

(30) Foreign Application Priority Data
Apr. 1, 2024 (JP) 2024-059213

(51) Int. Cl. H01L 23/495; H01L 23/00; H01L 23/29

(52) U.S. Cl. CPC H01L 23/49513; H01L 23/295; H01L 24/32; H01L 24/48; H01L 24/73; H01L 24/83; H01L 24/85; H01L 24/92; H01L 2224/32258; H01L 2224/48247; H01L 2224/73265; H01L 2224/83192; H01L 2224/83201; H01L 2224/851; H01L 2224/92247

(57) ABSTRACT

A first region of a die pad of a semiconductor device includes: a third region having a surface facing a surface of a semiconductor chip via a die bond material; and a fourth region having a surface facing the surface of the semiconductor chip via a sealing body without interposing the die bond material between the die pad and the semiconductor chip. The die pad includes a convex portion provided in the third region and protruding from a flat surface including an upper surface of the die pad toward the semiconductor chip. The sealing body includes a plurality of filler particles. A part of the plurality of filler particles is interposed between the surface of the semiconductor chip and the upper surface, which is located in the fourth region, of the die pad.

### CROSS-REFERENCE TO RELATED APPLICATIONS

The disclosure of Japanese Patent Application No. 2024-059213 filed on Apr. 1, 2024 including the specification, drawings and abstract is incorporated herein by reference in its entirety.

### BACKGROUND

The present invention relates to a semiconductor device and a method of manufacturing the same.

There are disclosed techniques listed below. Patent Document 1 Japanese Unexamined Patent Application Publication No. 2019-145625

There is a technique of mounting a semiconductor chip on a die pad via a die bond material (Japanese Patent Application Laid-Open No. 2019-145625)

### SUMMARY

When a semiconductor chip is mounted on a die pad via a die bond material, a space where the die bond material is not interposed between the semiconductor chip and the die pad may be generated. If the thickness of this space is thin, filler particles contained in a sealing material that seals the semiconductor chip and the die pad are less likely to be supplied into the space, which may cause peeling between the sealing material and the die pad.

Other problems and novel features would become apparent from the description of the present specification and the accompanying drawings.

According to one embodiment, a semiconductor device includes a die pad including a first surface having a first region and a second region surrounding the first region, a semiconductor chip including a second surface facing the first surface, the semiconductor chip being mounted on the first surface of the die pad at the first region via a die bond material, a plurality of wires, and a sealing body that seals the semiconductor chip, the plurality of wires, and the first surface of the die pad. The plurality of wires includes a first wire connected to the second region of the die pad. The first region of the die pad includes a third region having a surface facing the second surface of the semiconductor chip via the die bond material, and a fourth region having a surface facing the second surface of the semiconductor chip via the sealing body. The die pad includes a first convex portion provided in the third region and protruding from a flat surface including the first surface toward the semiconductor chip. The sealing body includes a plurality of filler particles. A part of the plurality of filler particles is interposed between the second surface of the semiconductor chip and the first surface, which is located in the fourth region, of the die pad.

According to another embodiment, a semiconductor device includes a die pad, a semiconductor chip, a plurality of wires, and a sealing body. The die pad includes a first surface, a plurality of through holes, a central portion including a center of the first surface, a peripheral edge portion at a peripheral edge of the first surface, and a plurality of connecting portions disposed between the plurality of through holes in plan view and extending so as to connect the central portion and the peripheral edge portion with each other. The semiconductor chip includes a second surface facing the first surface, a third surface opposite the second surface, and a plurality of electrodes arrayed on the third surface, the semiconductor chip being mounted in a chip mounting region of the first surface of the die pad via a die bond material. The sealing body seals the semiconductor chip, the plurality of wires, and the first surface of the die pad. The plurality of wires includes a first wire connected to the peripheral edge portion of the die pad. The die pad includes a groove portion formed at each of the plurality of connecting portions. The groove portion includes a first portion exposed from the die bond material and facing the second surface of the semiconductor chip via the sealing body, and a second portion located at a position not overlapping the semiconductor chip. A first distance from a bottom surface of the first portion of the groove portion to the second surface of the semiconductor chip is larger than a second distance from a flat surface including the first surface of the central portion to the second surface of the semiconductor chip. The sealing body includes a plurality of filler particles. A part of the plurality of filler particles is interposed between the second surface of the semiconductor chip and the first portion of the groove portion of the die pad.

According to yet another embodiment, a method of manufacturing a semiconductor device includes (a) preparing a lead frame including a die pad having a first surface including a first region and a second region surrounding the first region in plan view, and a plurality of leads arrayed on a periphery of the die pad in plan view. The method of manufacturing the semiconductor device includes (b) preparing a semiconductor chip including a second surface, a third surface opposite the second surface, and a plurality of electrodes arrayed on the third surface, and mounting the semiconductor chip in the first region of the die pad via a die bond material such that the second surface faces the first surface. The method of manufacturing the semiconductor device includes (c) connecting a first wire to the second region of the die pad. The method of manufacturing the semiconductor device includes (d) forming a sealing body that seals the semiconductor chip, the first wire and the die pad with a resin containing a plurality of filler particles. In the (b), the first region of the die pad includes a third region having a surface facing the second surface of the semiconductor chip via the die bond material, and a fourth region having a surface facing the second surface of the semiconductor chip without the die bond material interposed therebetween. The die pad of the lead frame prepared in the (a) includes a first convex portion provided in the third region and protruding upward from a flat surface including the first surface. In the (d), a part of the plurality of filler particles is supplied between the second surface of the semiconductor chip and the first surface, which is located in the fourth region, of the die pad.

According to the above embodiment, the performance of the semiconductor device can be improved.

### BRIEF DESCRIPTION OF THE DRAWINGS

FIG. 1 is a top view of a semiconductor device according to an embodiment.

FIG. 2 is a cross-sectional view taken along line A-A in FIG. 1.

FIG. 3 is a transmission plan view of FIG. 1.

FIG. 4 is a plan view illustrating FIG. 3 in a state where a semiconductor chip and a plurality of wires are removed.

FIG. 5 is an enlarged plan view of a die pad illustrated in FIG. 3.

FIG. 6 is an enlarged plan view of the die pad illustrated in FIG. 3.

FIG. 7 is an enlarged cross-sectional view of the semiconductor device illustrated in FIG. 3 taken along line B-B in FIG. 5.

FIG. 8 is an enlarged cross-sectional view illustrating a semiconductor device that is an examination example in comparison with FIG. 7.

FIG. 9 is an enlarged plan view of a die pad that is a modification of the die pad in FIG. 5.

FIG. 10 is an enlarged plan view of a die pad that is a modification of the die pad in FIG. 6.

FIG. 11 is an enlarged cross-sectional view of the semiconductor device taken along line C-C in FIG. 9.

FIG. 12 is an enlarged plan view of a die pad that is another modification of the die pad in FIG. 5.

FIG. 13 is an enlarged plan view of a die pad that is another modification of the die pad in FIG. 6.

FIG. 14 is an enlarged cross-sectional view of the semiconductor device taken along line D-D in FIG. 13.

FIG. 15 is an enlarged cross-sectional view of the semiconductor device taken along line E-E in FIG. 13.

FIG. 16 is an enlarged plan view illustrating a modification of the die pad illustrated in FIG. 9.

FIG. 17 is an enlarged plan view illustrating a modification of the die pad illustrated in FIG. 10.

FIG. 18 is an explanatory diagram illustrating a flow of an assembly step of any of the plurality of semiconductor devices described with reference to FIGS. 1 to 17.

FIG. 19 is an enlarged plan view illustrating a lead frame prepared in a base material preparation step illustrated in FIG. 18.

FIG. 20 is an enlarged cross-sectional view illustrating a state where a semiconductor chip is mounted on a die pad of the lead frame illustrated in FIG. 19.

FIG. 21 is an enlarged plan view illustrating a state where a paste-like die bond material is applied onto the die pad in a die bonding step.

FIG. 22 is an enlarged cross-sectional view taken along line F-F in FIG. 21.

FIG. 23 is an enlarged cross-sectional view illustrating a state where the semiconductor chip is pressed against the die pad illustrated in FIG. 22 to spread the paste-like die bond material.

### DETAILED DESCRIPTION

### (Description of the Description Format, and Basic Terms and Usage in the Present Application)

In the present application, the descriptions of the embodiments are divided into a plurality of sections or the like as necessary for convenience, but these sections and the like are not independent and separate from each other unless otherwise specified, and are each part of a single example, a partial detail of one for the other, a modification of a part or all, and the like, regardless of the order of the descriptions. In addition, repeated description will be omitted for the same parts, in principle. Furthermore, each component in the embodiments is not essential unless otherwise specified, unless the component is theoretically in a limited number, or unless otherwise clearly indicated by the context.

Similarly, in the descriptions of the embodiments and the like, even if the material, composition, and the like are described as “X made of A” or the like, it does not mean that the material, composition, and the like do not include elements other than A unless otherwise specified or clearly indicated by the context. For example, it means “X containing A as a main component” in the context of the composition. Needless to say, for example, the term “silicon member” or the like is not limited to pure silicon, and it includes a member containing a silicon-germanium (SiGe) alloy, other multicomponent alloys containing silicon as a main component, other additives, or the like. In addition, the term “gold plating”, “Cu layer”, “nickel plating”, or the like includes not only a pure material but also a member containing gold, Cu, nickel, or the like as a main component, respectively, unless otherwise clarified.

Furthermore, when a specific numerical value or quantity is mentioned, the numerical value may be greater than or less than the specific numerical value unless otherwise specified, unless the number is theoretically limited to the mentioned value, or unless otherwise clearly indicated by the context.

In the drawings of the embodiments described below, the same or similar parts are denoted by the same or similar symbols or reference numerals, and the description will not be repeated in principle.

In the accompanying drawings, hatching or the like may be omitted even in a cross section when the illustration becomes complicated or the object is clearly distinguished from a void space. In this regard, the outline of the background may be omitted even for a hole closed in a planar manner when it is obvious from the description or the like. Furthermore, even if it is not a cross section, hatching or a dot pattern may be added to clearly indicate that the object is not a void space or to clearly indicate the boundary of a region.

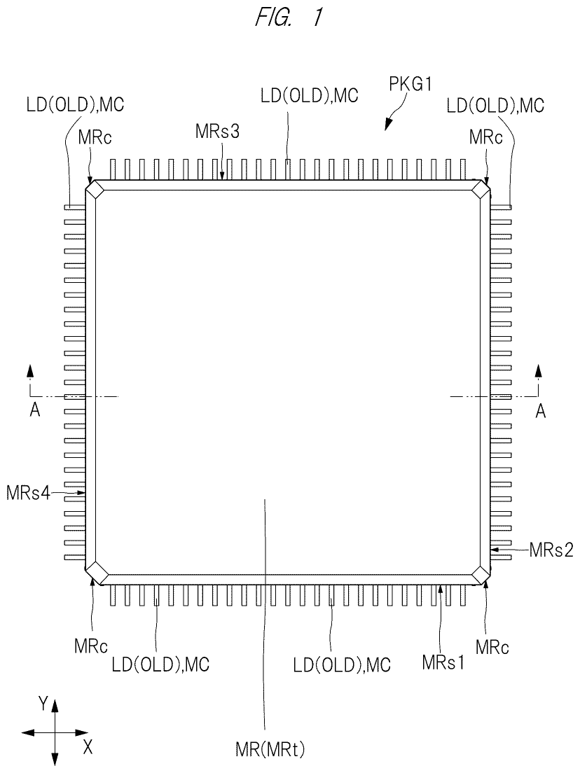

In the following description, directions referred to as an X direction, a Y direction, and a Z direction may be used. For example, the X direction and the Y direction are illustrated in FIG. 1 to be described later. The X direction and the Y direction intersect each other. In the example described below, the X direction is orthogonal to the Y direction. Hereinafter, an X-Y plane including the X direction and the Y direction will be described as a plane parallel to the main surface of a semiconductor device and the main surface of a mounting substrate.

A surface intersecting the X-Y plane (for example, a plane parallel to an X-Z plane including the X direction and the Z direction and a plane parallel to a Y-Z plane including the Y direction and the Z direction) is referred to as a side surface. In the following description, “planar view” means that a plane parallel to the X-Y plane is viewed unless it is clearly stated that the term should be otherwise interpreted. In addition, a normal direction with respect to the X-Y plane will be described as the “Z direction” or a thickness direction. “Thickness” and “height” mean the length in the “Z direction” unless it is clearly stated that the term should be otherwise interpreted. The X direction, the Y direction, and the Z direction are directions intersecting each other, more specifically, directions orthogonal to each other.

### <Semiconductor Device>

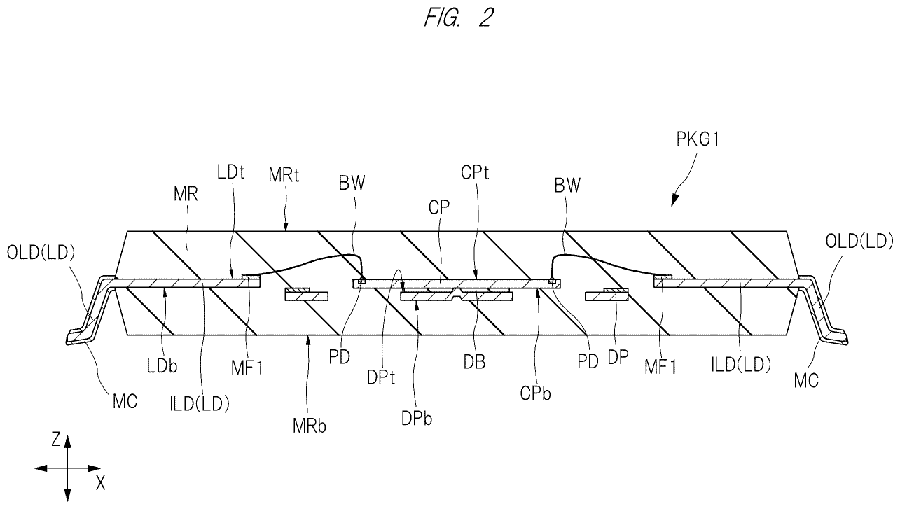

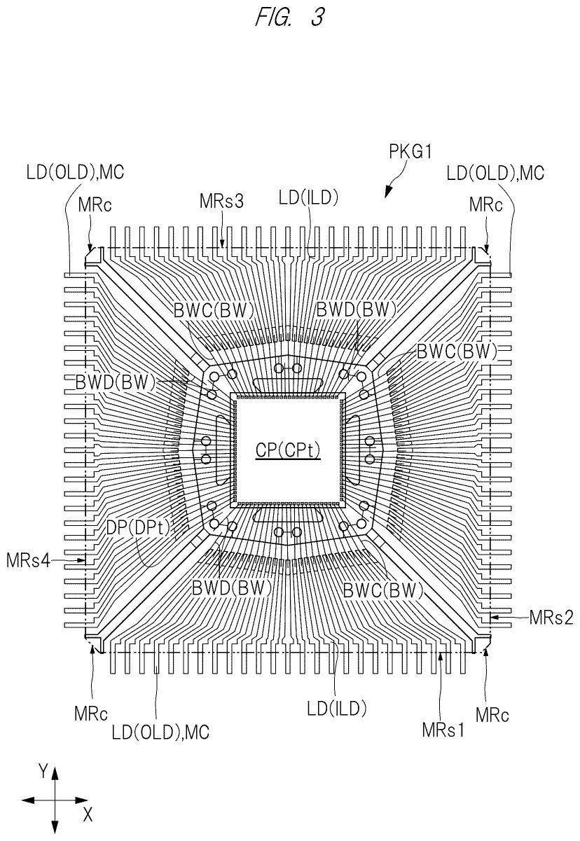

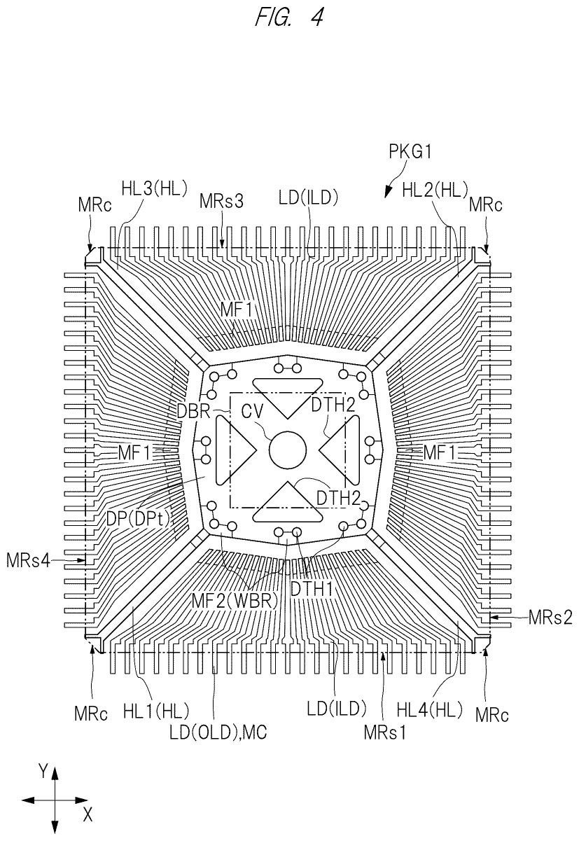

First, an outline of a configuration of a semiconductor device PKG1 of the present embodiment will be described with reference to FIGS. 1 to 4. FIG. 1 is a top view of a semiconductor device according to the present embodiment. FIG. 2 is a cross-sectional view taken along line A-A in FIG. 1. FIG. 3 is a transparent plan view illustrating an internal structure of the semiconductor device when seen through a sealing body illustrated in FIG. 1. FIG. 4 is a plan view illustrating FIG. 3 in a state where a semiconductor chip and a plurality of wires are removed.

As illustrated in FIGS. 1 to 4, the semiconductor device PKG1 includes a die pad DP (see FIGS. 2 and 3), a semiconductor chip CP (see FIGS. 2 and 3), a plurality of leads LD, and a plurality of wires BW (see FIG. 2). In addition, the semiconductor chip CP, the plurality of wires BW, and the die pad DP are sealed by a sealing body MR. The sealing body MR seals at least an upper surface DPt of the die pad DP. In the example illustrated in FIG. 2, the upper surface DPt and a lower surface DPb, both of which are flat surfaces, of the die pad DP are sealed by the sealing body. Although not illustrated, the lower surface DPb of the die pad DP may be exposed from the sealing body MR as a modification. An inner lead portion ILD (see FIG. 2) of each of the plurality of leads LD is sealed by the sealing body MR, and an outer lead portion OLD of each of the plurality of leads LD is exposed from the sealing body MR.

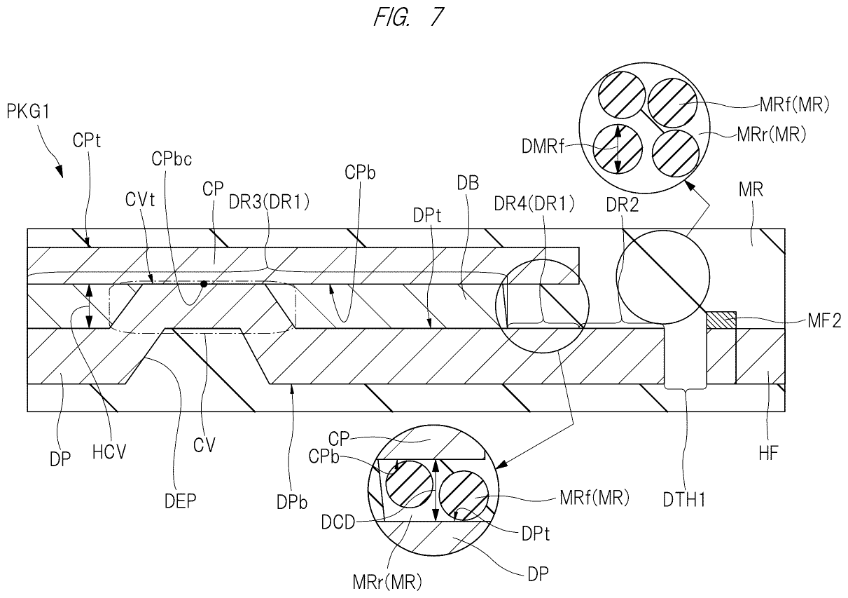

As illustrated in FIG. 1, the planar shape of the sealing body MR included in the semiconductor device PKG1 is a quadrangle (quadrilateral). The sealing body MR has an upper surface MRt, a lower surface (back surface, mounting surface) MRb located on the opposite side of the upper surface MRt (see FIG. 2), and a side surface located between the upper surface MRt and the lower surface MRb. As illustrated in FIG. 7 to be described later, the sealing body MR is made of an insulating material containing a filler particle MRf and a resin component MRr.

As illustrated in FIGS. 1 and 3, the sealing body MR has, in plan view, a side (main side) MRs1 extending (stretching) along the X direction and a side (main side) MRs2 extending along the Y direction intersecting the X direction (orthogonal to the X direction in FIG. 1). The sealing body MR has a side MRs3 located on the opposite side of the side MRs1 and extending along the X direction, and a side MRs4 located on the opposite side of the side MRs2 and extending along the Y direction. As illustrated in FIG. 1, four side surfaces of the sealing body MR are disposed along each side of the sealing body MR.

A corner portion MRC of the sealing body MR includes a peripheral region of a corner that is an intersection of any two intersecting sides (two main sides) among the four sides (four main sides) of the sealing body MR. Note that, strictly speaking, as illustrated in FIGS. 1 and 3, since the corner portion MRc of the sealing body MR has a tapered shape that does not include the intersection itself of the above-described four main sides, the intersection of the main sides is disposed outside the corner portion MRc of the sealing body MR. However, since the size of the corner portion MRc is sufficiently smaller than the length of the main side, the center of the corner portion MRc is regarded as the corner of the sealing body MR in the present application.

The semiconductor device PKG1 includes the plurality of leads LD arrayed along each side (each main side) of the sealing body MR having a quadrangular planar shape. Each of the plurality of leads LD is made of a metal material, and is, for example, a metal member made of copper or a copper alloy in the present embodiment.

As illustrated in FIG. 2, the outer lead portions OLD of the plurality of leads LD protrudes from the inside to the outside of the sealing body MR on the side surface of the sealing body MR. In addition, on the exposed surfaces of the outer lead portions OLD of the plurality of leads LD, for example, a metal film (exterior plating film) MC is formed on a surface of a base material containing copper as a main component. The metal film MC is, for example, a metal film made of a metal material having better wettability to solder than copper that is the base material, such as solder, and covering the surface of the copper member that is the base material. By forming the metal film MC made of solder or the like on each of the outer lead portions OLD of the plurality of leads LD that is external terminals of the semiconductor device PKG1, the wettability of a solder material that is a conductive connecting material can be improved when the semiconductor device PKG1 is mounted on a mounting substrate. This increases the bonding area between the plurality of leads LD and the solder material, thus making it possible to improve the bonding strength between the plurality of leads LD and a terminal on the mounting substrate side.

The metal film MC is, for example, a Sn—Pb solder material containing lead (Pb) or a solder material made of so-called lead-free solder containing substantially no Pb. Examples of the lead-free solder include tin (Sn), tin-bismuth (Sn—Bi), tin-copper-silver (Sn—Cu—Ag), and tin-copper (Sn—Cu). Here, the lead-free solder means that the content of lead (Pb) is 0.1 weight percent or less, and this content is defined as a standard of the Restriction of Hazardous Substances (RoHS) Directive.

As illustrated in FIG. 2, the semiconductor chip CP is sealed by the sealing body MR. As illustrated in FIG. 3, the semiconductor chip CP has a quadrangular shape in plan view, and a surface CPt is provided with a plurality of electrode pads (electrodes) PD (see FIG. 2) along each of four sides constituting the outer edge of the surface CPt. In addition, the semiconductor chip CP (specifically, a semiconductor substrate included in the semiconductor chip CP) is made of, for example, silicon (Si). Although not illustrated, a plurality of semiconductor elements (circuit elements) is formed on the main surface of the semiconductor chip CP (specifically, a semiconductor element formation region on an upper surface of the above semiconductor substrate included in the semiconductor chip CP). The plurality of electrode pads PD is electrically connected to the semiconductor elements via wiring (not illustrated) formed in a wiring layer disposed inside the semiconductor chip CP (specifically, between the surface CPt and the semiconductor element formation region (not illustrated)). That is, the plurality of electrode pads PD is electrically connected to circuits formed on the semiconductor chip CP.

The semiconductor chip CP has a surface (main surface, back surface, and lower surface) CPb and a surface (main surface, surface, upper surface) CPt opposite to the surface CPb. The plurality of electrode pads PD is arrayed on the surface CPt of the semiconductor chip CP.

Specifically, an insulating film covering the substrate and the wiring of the semiconductor chip CP are formed on the surface CPt of the semiconductor chip CP, and the surface of each of the plurality of electrode pads PD (see FIG. 2) is exposed from the insulating film at an opening formed on the insulating film. The electrode pad PD is made of metal, and, in the present embodiment, is made of aluminum (Al), for example. In the present specification, the expression “electrode pads PD arrayed on the surface CPt of the semiconductor chip CP” may be used, but strictly, the expression means the following: “Each of the plurality of electrode pads PD is exposed from the insulating film at any of the plurality of openings formed on the insulating film having the surface CPt of the semiconductor chip CP”.

As illustrated in FIG. 3, the plurality of leads LD is disposed around the die pad DP. Each of the plurality of leads LD is separated from the die pad DP. The electrode pads PD (see FIG. 2) arrayed on the surface CPt of the semiconductor chip CP are electrically connected to the inner lead portion ILD of the lead LD located inside the sealing body MR via the wire (conductive member) BW. The wire BW is made of, for example, gold (Au) or copper (Cu), and a part (for example, one end) of the wire BW is bonded to the electrode pad PD, and the other part (for example, the other end) is bonded to a wire bonding region at the distal end of the inner lead portion ILD.

In addition, a metal film (plating film, plating metal film) MF1 (see FIG. 2) is formed in the wire bonding region at the distal end of the inner lead portion ILD. As illustrated in FIG. 2, the metal film MF1 is formed on a part (an upper surface (surface) LDt of the distal end closest to the die pad DP) of the inner lead portion ILD. The metal film MF1 is made of, for example, a material containing silver (Ag) as a main component. Since the metal film MF1 made of a material containing silver as a main component is formed at a part of the inner lead portion ILD to which the wire BW is connected, the bonding strength with the wire BW made of gold or copper can be improved.

In the case of the semiconductor device PKG1 illustrated in FIGS. 1 to 3, a part of the plurality of wires BW has one end connected to the die pad DP and the other end connected to the electrode pad PD (see FIG. 2) of the semiconductor chip CP. Another part of the plurality of wires BW has one end connected to the die pad DP and the other end connected to the lead LD. In addition, still another part of the plurality of wires BW has one end connected to the electrode pad PD (see FIG. 2) of the semiconductor chip CP and the other end connected to the lead LD.

In other words, the plurality of wires BW includes a wire BWD connected to the die pad DP and a wire BWC connected to the semiconductor chip CP and the lead LD without through the die pad DP.

When a part of the plurality of wires BW is connected to the die pad DP as in the semiconductor device PKG1, the die pad DP can be used as a transmission path. The die pad DP has a larger cross-sectional area of the transmission path than the wire BW. Therefore, a potential transmitted via the die pad DP is less likely to change due to factors such as noise. For example, when the die pad DP is a supply path of a reference potential (for example, a ground potential), the reference potential can be stabilized (is made less likely to change due to the influence of noise or the like).

As illustrated in FIG. 2, the semiconductor chip CP is mounted on the die pad DP that is a chip mounting portion. The die pad DP includes the upper surface (main surface, chip mounting surface) DPt and the lower surface (main surface, back surface) DPb opposite to the upper surface DPt. The semiconductor chip CP is mounted on the upper surface DPt of the die pad DP. The semiconductor chip CP is mounted on a chip mounting region (chip mounting region, die bonding region) DBR (see FIG. 4) on the upper surface DPt of the die pad DP. The chip mounting region DBR is a region including the center of the upper surface DPt of the die pad DP. The outline of the chip mounting region DBR coincides with the outer edge of the semiconductor chip CP in plan view.

In the example illustrated in FIGS. 3 and 4, the outer edge of the upper surface DPt of the die pad DP forms an octagon. The die pad DP is a support member that supports the semiconductor chip CP, and has various modifications in shape and size other than the example illustrated in FIG. 4. For example, the planar shape of the die pad DP may be a quadrangle or more-polygonal shape.

As illustrated in FIG. 4, a metal film (plating film, plating metal film) MF2 is formed on a peripheral edge portion of the die pad DP. The metal film MF2 is made of, for example, a material containing silver (Ag) or gold (Au) as a main component. The metal film MF2 is made of the same metal material as the metal film MF1 formed on the upper surface of the distal end of each of the plurality of leads LD, and is formed by plating.

As described above, in the case of the present embodiment, a part of the plurality of wires BW is connected to the die pad DP. From the viewpoint of improving the connection reliability of the wire BW connected to the die pad DP, it is preferable that the metal film MF2 is formed at the portion where the wire BW is connected to the die pad DP.

In the case of the present embodiment, the metal film MF2 is formed on the upper surface DPt of the die pad DP in a wire bonding region WBR to which the wire BW (see FIG. 3) may be connected on the upper surface DPt of the die pad DP. In other words, the portion where the metal film MF2 is formed on the die pad DP illustrated in FIG. 4 is a region to which the wire BW may be connected. The wire bonding region WBR is a planned region where the wire BW may be bonded according to the specification of the product. Therefore, the wire BW may not be bonded to the wire bonding region WBR depending on the product.

The metal film MF2 made of a metal material containing silver or gold as a main component has lower adhesive strength with the sealing body MR illustrated in FIG. 2 than the die pad DP made of copper. When a thermal load is applied to the semiconductor device PKG 1, for example, in a reflow process during mounting or a temperature cycle, stress is generated at an adhesion interface between the die pad DP and the sealing body MR due to a difference in linear expansion coefficient between the sealing body MR and the die pad DP. In the case of a large-area metal pattern such as the die pad DP, the stress caused by the thermal load is the largest at the peripheral edge portion of the die pad DP. For this reason, when the stress caused by the above-described thermal load is generated, peeling between the die pad DP and the sealing body MR may occur at the peripheral edge portion of the die pad DP. In particular, when the metal film MF2 and the sealing body MR adhere to each other at the peripheral edge portion of the die pad DP, the adhesion interface between the metal film MF2 and the sealing body MR is more easily peeled off than the adhesion interface between the die pad DP and the sealing body MR.

To address this issue, in the case of the present embodiment, a through hole DTH1 is formed at a position overlapping the metal film MF2 or around the metal film MF2. The through hole DTH1 is an opening portion penetrating through the die pad DP in the thickness direction. The sealing body MR is embedded in the through hole DTH1. In this case, even if the difference in linear expansion coefficient between the sealing body MR and the die pad DP is large when the thermal load is applied, a part of the sealing body MR embedded in the through hole DTH1 functions as an anchor that suppresses excessive expansion or excessive contraction of the sealing body MR. Therefore, it is possible to suppress peeling between the metal film MF2 and the sealing body MR or progress of peeling.

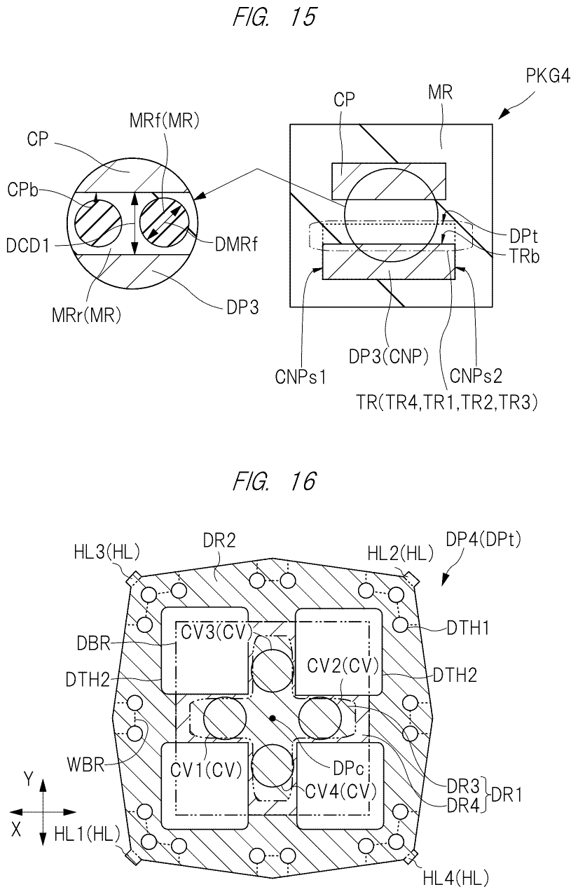

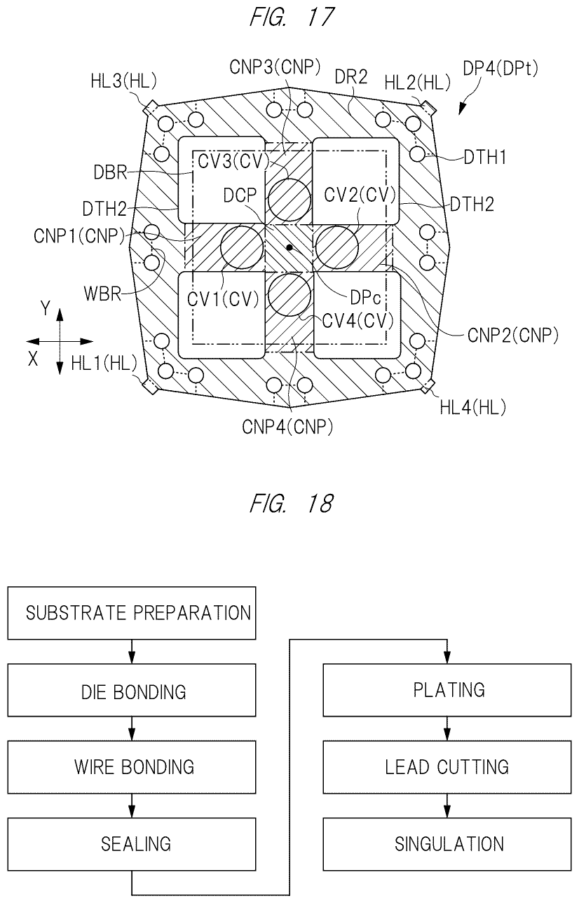

In addition, in the example illustrated in FIG. 4, the die pad DP includes a plurality of through holes DTH2 penetrating through the die pad DP in the thickness direction (Z direction illustrated in FIG. 2). As illustrated in FIG. 2, the surface CPb of the semiconductor chip CP is in contact with the sealing body MR at a position where each of the plurality of through holes DTH2 (see FIG. 4) is formed. The adhesive strength at the interface between the surface CPb of the semiconductor chip CP and the sealing body MR is higher than the adhesive strength at the interface between the die pad DP and the sealing body MR. Therefore, when a part of the surface CPb of the semiconductor chip CP is adhered to the sealing body MR as in the present embodiment, the sealing body MR can be suppressed from being peeled from the semiconductor chip CP or the die pad DP as compared with a case where the entire surface CPb of the semiconductor chip CP is not in contact with the sealing body MR. In the example illustrated in FIG. 4, the planar shape of each of the plurality of through holes DTH2 is a triangle. However, the planar shape of the through hole DTH2 is not limited to a triangle, and there are various modifications. For example, in the case of a die pad DP4 illustrated in FIGS. 16 and 17 to be described later, the shape of the through hole DTH2 is a quadrangle. Note that, as in the example illustrated in FIG. 4 and the example illustrated in FIG. 16 to be described later, a plurality of vertices of the triangle or the square may be partially or entirely R-processed (rounded). In the present specification, even if the vertex is R-processed in this manner, the R-processed portion is regarded as the vertex.

As illustrated in FIG. 2, the semiconductor chip CP is mounted on the die pad DP via a die bond material (adhesive material) DB in a state where the surface CPb faces the upper surface DPt of the die pad DP. That is, the semiconductor chip CP is mounted by a so-called face-up mounting method in which the surface CPb opposite to the surface CPt on which the plurality of electrode pads PD is formed faces the chip mounting surface (upper surface DPt). The die bond material DB is an adhesive material used when the semiconductor chip CP is die-bonded, and for example, a resin adhesive material containing metal particles made of silver or the like in an epoxy-based thermosetting resin, or a metal bond material such as a solder material is used.

As illustrated in FIG. 4, a plurality of hung leads (suspension leads) HL extending from the peripheral edge portion of the die pad DP toward a peripheral edge portion of the sealing body MR is disposed around the die pad DP. The hung lead (suspension lead) HL is a member that supports the die pad DP on a support portion (frame portion) of a lead frame in the manufacturing process of the semiconductor device PKG1, and one end of the hung lead HL is connected to the outer edge of the die pad DP.

In the example illustrated in FIG. 4, four hung leads HL1, HL2, HL3, and HL4 extending from a part of the die pad DP toward each of the four corner portions MRc of the sealing body MR are connected to the die pad DP. The hung lead HL2 is disposed on the opposite side of the hung lead HL1 across the die pad DP.

The hung lead HL4 is disposed on the opposite side of the hung lead HL3 across the die pad DP. A lead group including the plurality of leads LD is disposed between the hung lead HL1 and the hung lead HL3, between the hung lead HL1 and the hung lead HL4, between the hung lead HL2 and the hung lead HL3, and between the hung lead HL2 and the hung lead HL4.

One end of the plurality of hung leads HL is connected to a corner portion (corner) of the die pad DP. The other end of the plurality of hung leads HL extends toward the corner portion MRc of the sealing body MR, bifurcates in the vicinity of the corner portion MRc, and is exposed from the sealing body MR (see FIG. 1) at the side surface of the sealing body MR.

In the example illustrated in FIG. 2, the upper surface DPt of the die pad DP and an upper surface of the inner lead portion ILD of the lead LD are located at different heights. Specifically, for example, when the lower surface MRb of the sealing body MR is a reference surface, the height from the reference surface to the upper surface DPt of the die pad DP is lower than the height from the reference surface to the upper surface LDt of the inner lead portion ILD. For this reason, each of the plurality of hung leads HL illustrated in FIG. 3 is provided with an offset portion (bent portion, set-down portion in the example of the present embodiment) bent such that the height of the upper surface DPt of the die pad DP is located at a height different from the height of the upper surface LDt (see FIG. 2) of the inner lead portion ILD of the lead LD.

In addition, as illustrated in FIG. 2, each of the semiconductor chip CP, the die pad DP, the plurality of wires BW, and the plurality of leads LD is sealed by the sealing body MR. Specifically, the semiconductor chip CP, the die pad DP, and the plurality of wires BW are entirely sealed by the sealing body MR. In addition, a part (inner lead portion ILD) of each of the plurality of leads LD is sealed by the sealing body MR, and the other part (outer lead portion OLD) is exposed from the sealing body MR.

Although details will be described later, the sealing body MR includes a resin and a plurality of filler particles MRf (see FIG. 7 to be described later) mixed with the resin. The filler particles MRf are made of, for example, silica (inorganic material containing silicon dioxide as a main component). By mixing the filler particles MRf in the sealing body MR, the difference between the linear expansion coefficient of the semiconductor chip CP and the linear expansion coefficient of the sealing body MR can be reduced.

### <Details of Die Pad Periphery>

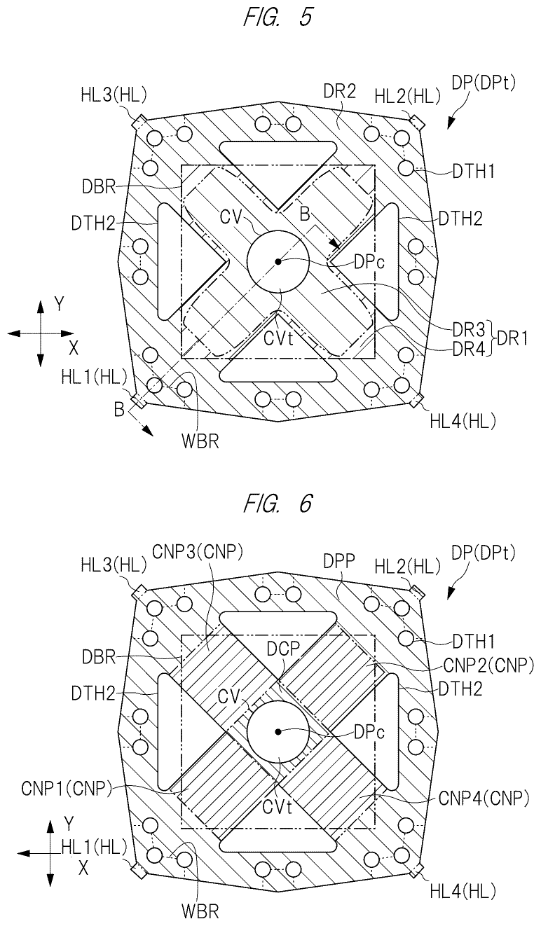

Next, details of a peripheral structure of the die pad DP illustrated in FIGS. 2 to 4 will be described. FIGS. 5 and 6 are enlarged plan views of the die pad illustrated in FIG. 3. Although FIG. 5 is a plan view, hatching is added to each region to clearly indicate the range of the region included in the upper surface DPt of the die pad DP. Although FIG. 6 is also a plan view, hatching is added to each portion to clearly indicate the range of the portion included in the die pad DP. FIG. 7 is an enlarged cross-sectional view of the semiconductor device illustrated in FIG. 3 taken along line B-B in FIG. 5.

As illustrated in FIG. 5, the upper surface DPt of the die pad DP includes a region DR1 and a region DR2 surrounding the periphery of the region DR1 in plan view. The region DR1 is the chip mounting region DBR that is a region where the semiconductor chip CP (see FIG. 3) is mounted, excluding a portion overlapping any of the plurality of through holes DTH2.

The region DR2 is a frame-shaped region continuously surrounding the periphery of the chip mounting region DBR. The region DR2 is a region of the upper surface DPt of the die pad DP excluding the region DR1, a portion overlapping any of the plurality of through holes DTH1, and a portion overlapping any of the plurality of through holes DTH2. Each of the plurality of wire bonding regions WBR is disposed in the region DR2. The region DR2 includes an outer edge of the upper surface DPt of the die pad DP.

In addition, the region DR1 includes a region DR3 and a region DR4. As illustrated in FIG. 7, the region DR3 is a region having a surface of the upper surface DPt facing the surface CPb of the semiconductor chip CP via the die bond material DB. In addition, the region DR4 includes a surface facing the surface CPb of the semiconductor chip CP via the sealing body MR, and is a region located closer to the region DR2 than the region DR3 in the example illustrated in FIG. 5. Note that, in FIG. 7, the region DR4 faces the semiconductor chip CP without interposing the die bond material DB between the die pad DP and the semiconductor chip CP. However, the resin component of the die bond material DB may ooze out in a part of the region DR4.

As illustrated in FIGS. 5 to 7, the die pad DP includes a convex portion CV provided in the region DR3 and protruding from a flat surface (reference surface) including the upper surface DPt toward the semiconductor chip CP. As illustrated in FIG. 7, a top surface CVt of the convex portion CV is located at a height different from the upper surface DPt of the die pad DP. Thus, the top surface CVt of the convex portion CV is not included in the upper surface DPt of the die pad DP. Therefore, precisely, the convex portion CV is located at a position surrounded by the region DR3. The sealing body MR includes the plurality of filler particles MRf. A part of the plurality of filler particles MRf is interposed between the surface CPb of the semiconductor chip CP and the region DR4 of the die pad DP.

In addition, the die pad DP of the present embodiment can be expressed as follows using FIG. 6. As illustrated in FIG. 6, the die pad DP includes a central portion DCP including a center DPc of the upper surface DPt, a peripheral edge portion DPP, and a plurality of connecting portions CNP disposed between the plurality of through holes DTH2 in plan view and extending so as to connect the central portion DCP and the peripheral edge portion DPP with each other. The plurality of connecting portions CNP includes a connecting portion CNP1 extending from the central portion DCP toward the peripheral edge portion DPP, and a connecting portion CNP2 disposed on the opposite side of the connecting portion CNP1 across the central portion DCP. In addition, the plurality of connecting portions CNP includes a connecting portion CNP3 extending from the central portion DCP toward the peripheral edge portion DPP, and a connecting portion CNP4 disposed on the opposite side of the connecting portion CNP3 across the central portion DCP. The connecting portion CNP1 is adjacent to each of the connecting portion CNP3 and the connecting portion CNP4 across the through hole DTH2. The connecting portion CNP2 is adjacent to each of the connecting portion CNP3 and the connecting portion CNP4 across the through hole DTH2.

Next, the reason why the region DR1 of the upper surface DPt of the die pad DP includes the region DR3 and the region DR4 will be described. Considering the mounting strength of the semiconductor chip CP, it is preferable that the die bond material DB (see FIG. 7) is entirely interposed between the surface CPb of the semiconductor chip CP and the die pad DP.

However, in the case of the structure in which the wire BW (see FIG. 3) is connected to the wire bonding region WBR located in the peripheral edge region of the die pad DP as in the present embodiment, it is necessary to prevent the die bond material DB from spreading too much toward the peripheral edge of the upper surface DPt and reaching the wire bonding region WBR.

In addition, when the flat surface area of the semiconductor chip CP (the area of the surface CPt illustrated in FIG. 3) is relatively large with respect to the area of the upper surface DPt of the die pad DP as in the present embodiment, the distance from the outer edge of the chip mounting region DBR to the wire bonding region WBR may be short as illustrated in FIG. 4.

In this case, to prevent the die bond material DB from reaching the wire bonding region WBR, it is preferable to limit the application amount of the die bond material DB so that the die bond material DB does not reach the wire bonding region WBR outside the chip mounting region DBR. Since it is difficult to stop the die bond material DB at the boundary between the chip mounting region DBR and the region R2, the die bond material DB is designed to stop spreading within the chip mounting region DBR when the margin is considered. As a result, the region DR1 of the die pad DP includes the region DR3 covered with the die bond material DB and the region DR4 exposed from the die bond material DB.

Alternatively, when the die pad DP includes the plurality of through holes DTH2 as in the present embodiment, it is necessary to limit the application amount of the die bond material DB (see FIG. 7) for the following reason.

The die bond material DB spreads to the periphery by being pressed by the semiconductor chip CP after being applied to the chip mounting region DBR (specifically, the central portion DCP and the connecting portion CNP) illustrated in FIG. 6.

At this time, if the application amount of the die bond material DB (see FIG. 7) is large, the die bond material DB may wrap around to the side surface of the through hole DTH2. When the die bond material DB wraps around to the side surface of the through hole DTH2, it becomes difficult to control the separation distance (distance) between the semiconductor chip CP and the die pad DP. For this reason, it is necessary to avoid the die bond material DB from wrapping around to the side surface of the through hole DTH2. Thus, the application amount of the die bond material DB is limited. As a result, the region DR1 of the die pad DP includes the region DR3 covered with the die bond material DB and the region DR4 exposed from the die bond material DB.

As described above, in the case of the semiconductor device PKG1 having a structure in which a part of the plurality of wires BW is bonded to the die pad DP, the chip mounting region DBR may include the region DR4 exposed from the die bond material DB regardless of whether or not the die pad DP has the through hole DTH2. In addition, in the case of the semiconductor device PKG1 having the through hole DTH2 at a position overlapping the chip mounting region DBR as in the present embodiment, there is a high possibility that the region DR1 of the die pad DP includes the region DR4 exposed from the die bond material DB.

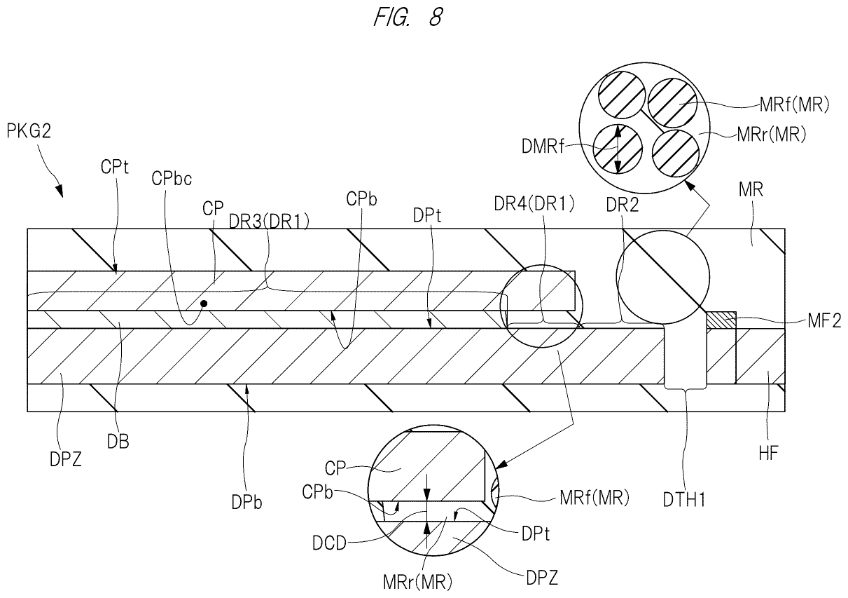

As illustrated in FIG. 7, the sealing body MR is embedded between the region DR4 and the surface CPb of the semiconductor chip CP. However, in the case of a die pad having a structure in which the convex portion CV is not provided, it has been found that the following problem occurs, as illustrated in FIG. 8 as an examination example. FIG. 8 is an enlarged cross-sectional view illustrating a semiconductor device that is the examination example in comparison with FIG. 7.

A semiconductor device PKG2 illustrated in FIG. 8 is different from the semiconductor device PKG1 illustrated in FIG. 7 in that the convex portion CV illustrated in FIG. 7 is not formed. When the convex portion CV is not formed, since the distance between the semiconductor chip CP and the die pad DPZ can be shortened in the step of mounting the semiconductor chip CP on the die pad DPZ, the value of a distance DCD from the upper surface DPt of the die pad DPZ to the surface CPb of the semiconductor chip CP in the region DR4 is small.

In the example illustrated in FIG. 8, the value of the distance DCD is smaller than the average value of the particle diameters DMRf of the plurality of filler particles MRf included in the sealing body MR. Hereinafter, the average value of the particle diameters DMRf of the plurality of filler particles MRf included in the sealing body MR may be referred to as an average particle diameter DMRf. For example, the average particle diameter DMRf of the plurality of filler particles MRf is larger than 25 μm and less than 30 μm. The distance DCD between the upper surface DPt of the die pad DPZ and the surface CPb of the semiconductor chip CP in the region DR4 is, for example, less than 5 μm. In this case, since the application amount itself of the die bond material DB can be reduced, the value was considered to be preferable.

### <Peeling Between Sealing Body and Die Pad>

However, according to the examination by the inventor of the present application, it has been found that, in the case of the semiconductor device PKG2 illustrated in FIG. 8, a cavity may be generated between the sealing body MR and the die pad DPZ in the region DR4. In addition, it has been found that peeling between the sealing body MR and the die pad DPZ progresses from the cavity. On the upper surface DPt of the die pad DPZ, an oxide film (for example, a copper oxide film) is formed, and the oxide film and the sealing body MR are firmly bonded to each other in the region DR2. Therefore, it has been found that the peeling progresses between the oxide film of the die pad DPZ and the base material in the region DR2.

As described above, in the case of the present embodiment, the wire bonding region WBR (see FIG. 4) to which the wire BW (see FIG. 3) is bonded is provided in the peripheral edge portion of the die pad DP illustrated in FIG. 7. For this reason, if the above-described peeling progresses and reaches the wire bonding region WBR, it causes a reduction in the electrical connection reliability between the wire BW and the die pad DPZ (see FIG. 8).

The cause of the above-described peeling is considered as follows. That is, in the step of forming the sealing body MR illustrated in FIG. 8, the sealing body MR is embedded between the region DR4 of the die pad DPZ and the semiconductor chip CP. At this time, since the distance DCD between the semiconductor chip CP and the die pad DPZ is small, the filler particle MRf contained in the sealing body MR is less likely to enter between the semiconductor chip CP and the die pad DPZ. As a result, the sealing body MR embedded between the semiconductor chip CP and the region DR4 of the die pad DPZ is in a state where the concentration of the resin component MRr is higher than that of the sealing body MR in other regions. In other words, the density of the filler particle MRf between the semiconductor chip CP and the region DR4 of the die pad DPZ is lower than the density of the filler particle MRf in other regions. Therefore, the shrinkage rate of the sealing body MR between the semiconductor chip CP and the die pad DPZ is higher than the shrinkage rate of the sealing body MR in other portions.

When the sealing body MR is cured (in other words, the thermosetting resin component is cured by cure baking) in this state, the above-described cavity (shrinkage cavity or porosity) is generated at a portion where the adhesive force with the sealing body MR is relatively weak and in a region where a stress due to a temperature change is particularly strongly applied.

In the case of the present embodiment, since the adhesive force between the semiconductor chip CP and the sealing body MR is high, the cavity is generated at the interface between the die pad DPZ and the sealing body MR. In addition, since stress is applied particularly strongly in the vicinity of the boundary between the region DR2 and the region DR4, the cavity is generated in the vicinity of the boundary between the region DR2 and the region DR4.

By a method such as forming a copper oxide film on the upper surface DPt of the die pad DP or roughening the upper surface DPt, the adhesive force between the upper surface DPt of the die pad DP and the sealing body MR can be improved. However, when the resin component of the die bond material DB oozes out in the region DR4 of the die pad DPZ as described above, the sealing body MR adheres to the die pad DPZ via the oozed resin component. The adhesive force between the sealing body MR and the oozed resin component is relatively lower than the adhesive force between the sealing body MR and the semiconductor chip CP. Therefore, for example, even if the oxide film is formed on the upper surface DPt of the die pad DP, the above-described cavity is generated at the interface between the oozed resin and the sealing body MR when the sealing body MR is cured.

Based on the above examination results, the inventor of the present application has examined a technique capable of preventing the cavity from being generated between the semiconductor chip CP and the die pad DPZ. As a result of the examination, it has been found that the generation of the cavity can be suppressed when the filler particle MRf is interposed between the semiconductor chip CP and the die pad DP as illustrated in FIG. 7.

Specifically, when the filler particle MRf is interposed between the semiconductor chip CP and the die pad DP, the sealing body MR filled between the semiconductor chip CP and the die pad DP in a sealing step can be prevented from shrinking at an extremely high shrinkage rate. The filler particle MRf is, for example, an inorganic particle such as silica, and has a smaller linear expansion coefficient value than the resin component MRr containing a thermosetting resin. Therefore, when the sealing body MR disposed between the semiconductor chip CP and the die pad DP includes the filler particle MRf at a density similar to that of the sealing body MR at other portions, the value of the shrinkage rate of the sealing body MR disposed between the semiconductor chip CP and the die pad DP can be reduced. Since the principle of generation of the cavity (shrinkage cavity or porosity) is as described above, if the shrinkage rate of the sealing body MR disposed between the semiconductor chip CP and the die pad DP can be reduced, generation of the cavity can be prevented or suppressed.

Incidentally, although only the filler particle MRf having a size close to the average particle diameter DMRf is illustrated in FIGS. 7 and 8, the plurality of filler particles MRf may include a particle having an extremely small size as compared with the average particle diameter DMRf (hereinafter, referred to as a microparticle). The microparticle includes, for example, a crushed particle obtained when a part of the plurality of filler particles MRf is crushed, and the particle diameter thereof is 20% or less of the average particle diameter DMRf of the plurality of filler particles. When the filler particle MRf is a purchased product classified in advance, the particle diameter defined in the specification of the purchased product can be set as the average particle diameter DMRf of the plurality of filler particles MRf. Alternatively, when the average particle diameter DMRf of the plurality of filler particles MRf is determined by measurement, all the filler particles MRf included in the unit volume are extracted, and the average value of the particle diameters of the filler particles MRf from which microparticles (for example, those having a particle diameter of less than 5 μm) are excluded can be defined as the average particle diameter DMRf.

When only the microparticles (for example, those having a particle diameter of less than 5 μm) are included between the semiconductor chip CP and the die pad DP, the effect of reducing the shrinkage rate of the sealing body MR is small. It is difficult to fill only the microparticles between the semiconductor chip CP and the die pad DP at a high density (a density similar to the density of the filler particle MRf in the sealing body MR at other portions). Thus, the effect of reducing the shrinkage rate is small because, when the filler particle MRf interposed between the semiconductor chip CP and the die pad DP is only a microparticle, the ratio of the resin component MRr increases in the sealing body MR.

Therefore, it is more preferable that the filler particles MRf having a large particle diameter to some extent, more specifically, a plurality of filler particles MRf including a filler particle having the average value or more, are interposed between the semiconductor chip CP and the die pad DP. From this viewpoint, it is preferable that the distance DCD from the upper surface DPt of the die pad DP to the surface CPb of the semiconductor chip CP in the region DR4 illustrated in FIG. 7 is larger than the average particle diameter DMRf of the plurality of filler particles MRf. For example, in the example illustrated in FIG. 7, the average particle diameter DMRf of the plurality of filler particles MRf is larger than 25 μm and smaller than 30 μm. On the other hand, the distance DCD from the upper surface DPt of the die pad DP to the surface CPb of the semiconductor chip CP in the region DR4 is preferably 30 μm or more.

In the case of the present embodiment, as illustrated in FIG. 7, the convex portion is formed in the region DR3 of the die pad DP, and thus the distance DCD from the upper surface DPt of the die pad DP to the surface CPb of the semiconductor chip CP in the region DR4 is equal to or larger than a protrusion height HCV of the convex portion CV, no matter how strongly the semiconductor chip CP is pressed in the step of mounting the semiconductor chip CP on the die pad DP. Note that the protrusion height HCV of the convex portion CV is defined as a height difference between the top surface CVt of the convex portion CV and the reference surface that is the height of the upper surface DPt of the die pad DP in the region DR3.

It is preferable that the protrusion height HCV of the convex portion CV is larger than the average particle diameter DMRf of the plurality of filler particles MRf. For example, in the example illustrated in FIG. 7, the protrusion height HCV of the convex portion CV is preferably 30 μm or more.

In the example illustrated in FIG. 7, the surface CPb of the semiconductor chip CP and the top surface CVt of the convex portion CV are in contact with each other. Although not illustrated, the die bond material DB may be interposed between the surface CPb of the semiconductor chip CP and the top surface CVt of the convex portion CV as a modification of the die pad in FIG. 7. However, from the viewpoint of reducing variations in the separation distance (distance) between the semiconductor chip CP and the die pad DP, even if the die bond material DB is interposed between the semiconductor chip CP and the convex portion CV, it is preferable that the thickness of the die bond material DB disposed between the semiconductor chip CP and the convex portion CV is substantially small enough to be negligible.

In addition, from the viewpoint of reducing variations in the separation distance (distance) between the semiconductor chip CP and the die pad DP, it is particularly preferable that the surface CPb of the semiconductor chip CP and the top surface CVt of the convex portion CV are in contact with each other. It is preferable that the top surface CVt is a flat surface parallel to the upper surface DPt of the die pad DP. As a result, the surface CPb and the top surface CVt of the convex portion CV can be easily disposed in parallel with each other.

In the case of the present embodiment, the die pad DP has one convex portion CV. In the case of one convex portion CV, it is preferable that the convex portion CV is disposed so as to include the center DPc of the die pad in consideration of the balance when the semiconductor chip CP is mounted. Therefore, as illustrated in FIG. 7, the convex portion CV faces a center CPbc of the surface CPb of the semiconductor chip CP.

Note that, from the viewpoint of reducing variations in the separation distance (distance) between the semiconductor chip CP and the die pad DP, a modification is conceivable in which a plurality of convex portions CV are provided on the die pad DP. This modification will be described later.

In the example illustrated in FIGS. 5 and 6, the top surface CVt of the convex portion CV is circular. However, the shape of the top surface CVt is not limited to the circular shape, and may be, for example, a triangular, quadrangle, or more-polygonal shape.

In addition, the convex portion CV is formed by pressing using a mold, for example. For this reason, as illustrated in FIG. 7, a depressed portion DEP is formed on the lower surface DPb of the die pad DP on the opposite side of the convex portion CV.

### <Modification of Convex Portion Layout>

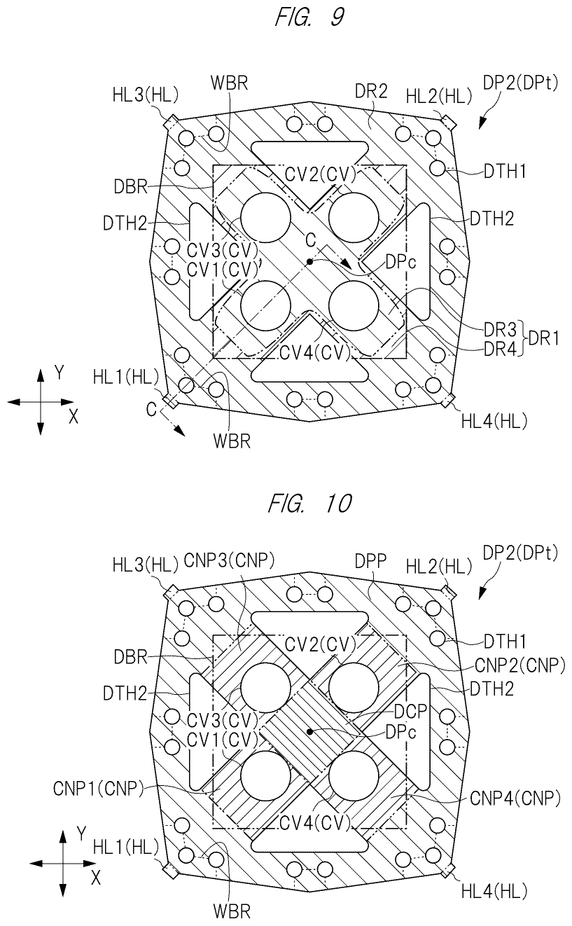

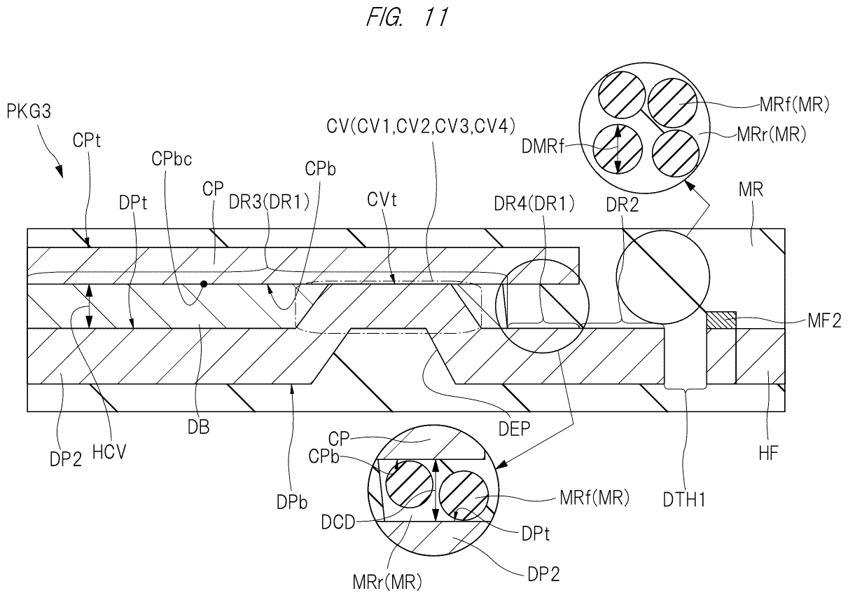

Next, modifications of the layout of the convex portion described with reference to FIGS. 5 to 7 will be described. FIG. 9 is an enlarged plan view of a die pad that is a modification of the die pad in FIG. 5. FIG. 10 is an enlarged plan view of a die pad that is a modification of the die pad in FIG. 6. FIG. 11 is an enlarged cross-sectional view of the semiconductor device taken along line C-C in FIG. 9. A plurality of convex portions CV illustrated in FIGS. 9 and 10 is the same in structure as each other. Therefore, in FIG. 11, a convex portion CV1 disposed on line C-C in FIG. 9 is illustrated as a representative example, but the reference signs of a convex portion CV2, a convex portion CV3, and a convex portion CV4 are also indicated.

A semiconductor device PKG3 illustrated in FIG. 11 is different from the semiconductor device PKG1 in that the semiconductor device PKG3 includes a die pad DP2 (see FIG. 11) instead of the die pad DP of the semiconductor device PKG1 illustrated in FIG. 7.

The die pad DP2 illustrated in FIGS. 9 to 11 is different from the die pad DP described with reference to FIGS. 5 to 7 in the number of convex portions CV and the layout of the convex portion CV. As illustrated in FIG. 10, the die pad DP2 includes the central portion DCP including the center DPc of the upper surface DPt, the peripheral edge portion DPP included in the region DR2 (see FIG. 9), and the plurality of connecting portions CNP disposed between the plurality of through holes DTH2 in plan view and extending so as to connect the central portion DCP and the peripheral edge portion DPP with each other. The plurality of connecting portions CNP includes the connecting portion CNP1 extending from the central portion DCP toward the peripheral edge portion DPP, the connecting portion CNP2 disposed on the opposite side of the connecting portion CNP1 across the central portion DCP, the connecting portion CNP3 extending from the central portion DCP toward the peripheral edge portion DPP, and the connecting portion CNP4 disposed on the opposite side of the connecting portion CNP3 across the central portion DCP. This feature is the same as that of the die pad DP described with reference to FIGS. 5 to 7.

The die pad DP2 of the present modification includes a convex portion CV1 provided in the region DR3 of the connecting portion CNP1 and protruding from the flat surface (reference surface) including the upper surface DPt toward the semiconductor chip CP (see FIG. 11), and a convex portion CV2 provided in the region DR3 of the connecting portion CNP2 and protruding from the flat surface (reference surface) including the upper surface DPt toward the semiconductor chip CP (see FIG. 11) at the same protrusion height HCV (see FIG. 11) as the convex portion CV1.

Furthermore, the die pad DP2 includes a convex portion CV3 provided in the region DR3 of the connecting portion CNP3 and protruding from the flat surface (reference surface) including the upper surface DPt toward the semiconductor chip CP (see FIG. 11) at the same protrusion height HCV (see FIG. 11) as the convex portion CV1, and a convex portion CV4 provided in the region DR3 of the connecting portion CNP4 and protruding from the flat surface (reference surface) including the upper surface DPt toward the semiconductor chip CP (see FIG. 11) at the same protrusion height HCV (see FIG. 11) as the convex portion CV1.

As illustrated in FIG. 11, the top surface CVt of each of the convex portion CV1, the convex potion CV2, the convex portion CV3, and the convex portion CV4 is located at a height different from the upper surface DPt of the die pad DP. Thus, the top surface CVt of each of the plurality of convex portions CV is not included in the upper surface DPt of the die pad DP. Therefore, precisely, each of the plurality of convex portions CV is located at a position surrounded by the region DR3.

In the case of the present modification, the semiconductor chip CP can be supported by the plurality of convex portions CV. Therefore, the surface CPb of the semiconductor chip CP is less likely to be inclined with respect to the upper surface DPt of the die pad DP. In other words, in the case of the present modification, the semiconductor chip CP can be easily mounted such that the surface CPb of the semiconductor chip CP and the upper surface DPt of the die pad DP are parallel to each other. As a result, the value of the distance DCD between the surface CPb and the upper surface DPt in the region DR4 illustrated in FIG. 11 is less likely to vary and is substantially the same value as the protrusion height HCV of each of the plurality of convex portions CV. For this reason, the filler particle MRf (specifically, the filler particle MRf having a particle diameter close to the average particle diameter DMRf) is easily supplied between the region DR4 of the die pad DP and the semiconductor chip CP.

Therefore, according to the present modification, the generation of the cavity and the occurrence of the peeling caused by the cavity can be further stably suppressed, as compared with the die pad DP illustrated in FIGS. 5 to 7.

Incidentally, from the viewpoint of stably supporting the semiconductor chip CP as compared with the die pad DP illustrated in FIGS. 5 to 7, it is only necessary to provide at least a set of the convex portions CV1 and CV2 or a set of the convex portions CV3 and CV4 among the four convex portions CV illustrated in FIGS. 9 and 10.

For example, when only the set of at least the convex portion CV1 and the convex portion CV2 among the four convex portions CV illustrated in FIG. 9 is formed, the semiconductor chip CP can be prevented from being inclined with respect to the die pad DP in the direction along line C-C in FIG. 9.

As described above, the plurality of hung leads HL supporting the die pad DP are connected to the die pad DP. Each of the connecting portion CNP1 and the connecting portion CNP2 illustrated in FIG. 10 is disposed on an extension line of the hung lead HL1 (and on an extension line of the hung lead HL2) among the plurality of leads LD. The wire bonding region WBR to which the wire BWD (see FIG. 3) is connected is provided between the connecting portion CNP1 and the hung lead HL1. When only the set of the convex portion CV1 and the convex portion CV2 illustrated in FIG. 9 is provided, as described above, the semiconductor chip CP can be suppressed from being inclined in the direction along line C-C in FIG. 9. Thus, since the cavity causing the peeling is less likely to occur between the convex portion CV1 and the wire bonding region WBR, it is also possible to prevent the peeling from progressing to the wire bonding region WBR.

When the four convex portions CV are formed as illustrated in FIGS. 9 and 10, the semiconductor chip CP can be suppressed from being inclined with respect to the die pad DP in a direction orthogonal to line C-C in addition to the direction along line C-C illustrated in FIG. 9. Therefore, the generation of the cavity that causes the peeling can be prevented between each of the plurality of convex portions CV, and the chip mounting region DBR and the outer edge. In this respect, it is particularly preferable that the four convex portions CV are formed as illustrated in FIGS. 9 and 10.

In addition, each of the connecting portion CNP3 and the connecting portion CNP4 illustrated in FIG. 10 is disposed on an extension line of the hung lead HL3 (and on an extension line of the hung lead HL4) among the plurality of leads LD. The wire bonding region WBR to which the wire BWD (see FIG. 3) is connected is provided between the connecting portion CNP3 and the hung lead HL3. As described above, in the case of the present modification, since the cavity causing the peeling is less likely to occur between each of the plurality of convex portions CV and the wire bonding region WBR, it is also possible to prevent the peeling from progressing to the wire bonding region WBR.

In addition, although FIGS. 9 and 10 illustrate an example in which the four convex portions CV are provided, the number of convex portions CV may be five or more as a further modification. For example, in addition to the four convex portions CV illustrated in FIGS. 9 and 10, as illustrated in FIGS. 5 and 6, a fifth convex portion CV can be located at a position overlapping the center DPc of the upper surface DPt.

As in the example described with reference to FIG. 7, the surface CPb of the semiconductor chip CP and the top surface CVt of each of the plurality of convex portions CV are in contact with each other in the example illustrated in FIG. 11. Although not illustrated, the die bond material DB may be interposed between the surface CPb of the semiconductor chip CP and the top surface CVt of the convex portion CV as a modification of the die pad in FIG. 11. However, from the viewpoint of reducing variations in the separation distance (distance) between the semiconductor chip CP and the die pad DP, even if the die bond material DB is interposed between the semiconductor chip CP and the convex portion CV, it is preferable that the thickness of the die bond material DB disposed between the semiconductor chip CP and the convex portion CV is substantially small enough to be negligible.

In addition, the planar shape of the top surface CVt illustrated in FIG. 11 is the same as that of the top surface CVt of the convex portion CV described with reference to FIGS. 5 to 7. In addition, each of the convex portions CV of the four convex portions of the present modification is formed by pressing using a mold, for example. For this reason, as illustrated in FIG. 11, the depressed portion DEP is formed on the lower surface DPb of the die pad DP on the opposite side of each of the plurality of convex portions CV.

The die pad DP2 and the semiconductor device PKG3 (see FIG. 11) illustrated in FIGS. 9 to 11 are the same as the die pad DP and the semiconductor device PKG1 described with reference to FIGS. 1 to 7 except for the above-described difference. Therefore, redundant description will be omitted.

### <Modification to Prevent Peeling>

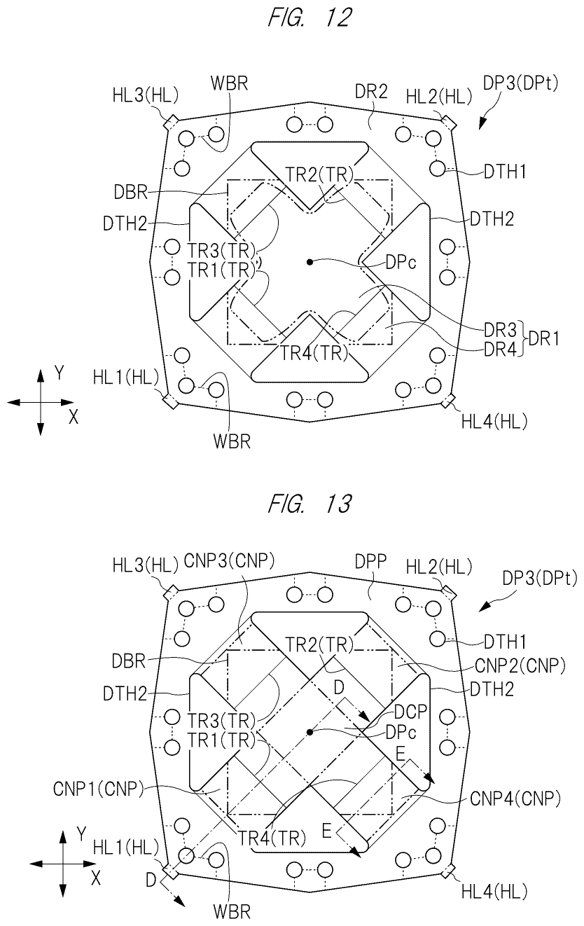

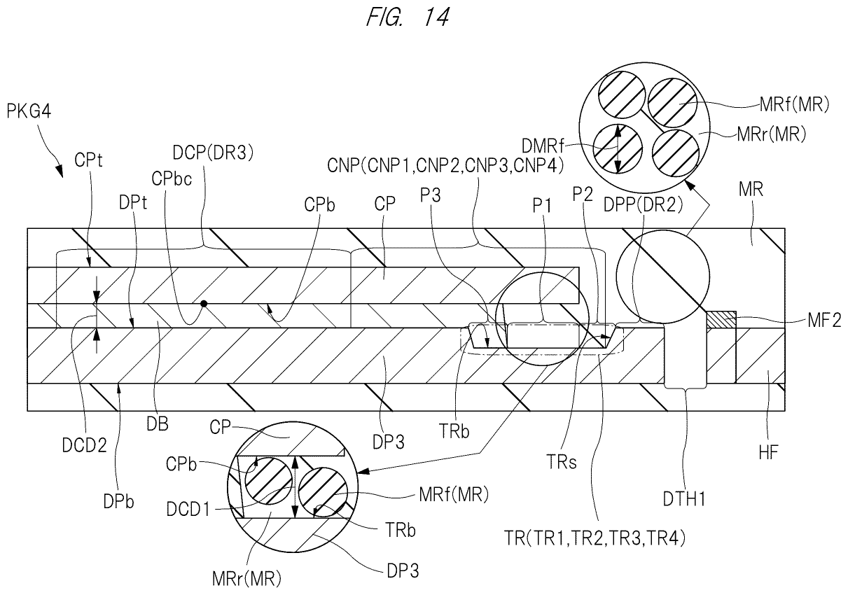

Next, as a modification to prevent the peeling, a countermeasure different from the convex portion CV described with reference to FIGS. 5 to 11 will be described. FIG. 12 is an enlarged plan view of a die pad that is another modification of the die pad in FIG. 5. FIG. 13 is an enlarged plan view of a die pad that is another modification of the die pad in FIG. 6. FIG. 14 is an enlarged cross-sectional view of the semiconductor device taken along line D-D in FIG. 13. FIG. 15 is an enlarged cross-sectional view of the semiconductor device taken along line E-E in FIG. 13.

Note that the plurality of connecting portions CNP illustrated in FIGS. 12 and 13 is the same in structure as each other. Therefore, in FIG. 14, the connecting portion CNP1 disposed on line D-D in FIG. 13 is illustrated as a representative example, but the reference signs of the connecting portion CNP2, the connecting portion CNP3, and the connecting portion CNP4 are also indicated. Similarly, in FIG. 14, a groove portion TR1 disposed on line D-D in FIG. 13 is illustrated as a representative example, but the reference signs of a groove portion TR2, a groove portion TR3, and a groove portion TR4 are also indicated. Similarly, in FIG. 15, the groove portion TR4 disposed on line E-E in FIG. 13 is illustrated as a representative example, but the reference signs of the groove portion TR1, the t groove portion TR2, and the groove portion TR3 are also indicated.

In addition, in FIGS. 12 and 13, hatching in FIGS. 5 and 6 is omitted for easy viewing of the positions and shapes of the plurality of groove portions TR. However, the range of each region included in the upper surface DPt of the die pad DP and the range of each portion included in the die pad DP are the same as those in FIGS. 5 and 6.

A semiconductor device PKG4 illustrated in FIG. 14 is different from the semiconductor device PKG1 in that the semiconductor device PKG4 includes a die pad DP3 instead of the die pad DP of the semiconductor device PKG1 illustrated in FIG. 7. The semiconductor device PKG4 has a structure that suppresses the occurrence of the above-described peeling by providing a plurality of groove portions TR instead of the one or the plurality of convex portions CV described with reference to FIGS. 5 to 11.

The die pad DP3 illustrated in FIG. 12 to FIG. 15 includes the upper surface DPt, the plurality of through holes DTH2 penetrating through the die pad DP3 in the thickness direction, the central portion DCP including the center DPc of the upper surface DPt, the peripheral edge portion DPP located at a peripheral edge of the die pad DP, and the plurality of connecting portions CNP disposed between the plurality of through holes DTH2 in plan view and extending so as to connect the central portion DCP and the peripheral edge portion DPP with each other. This feature is the same as that of the die pad DP illustrated in FIGS. 5 to 7.

As illustrated in FIGS. 12 and 13, the die pad DP3 includes the groove portion TR formed on each of the plurality of connecting portions CNP. As illustrated in FIG. 14, each of the plurality of groove portions TR includes a portion P1 exposed from the die bond material DB and facing the surface CPb of the semiconductor chip CP via the sealing body MR, and a portion P2 located at a position not overlapping the semiconductor chip CP. A distance DCD1 from a bottom surface TRb of the portion P1 of the groove portion TR to the surface CPb of the semiconductor chip CP is larger than a distance DCD2 from the upper surface DPt of the central portion DCP to the surface CPb of the semiconductor chip CP. A part of the plurality of filler particles MRf is interposed between the surface CPb of the semiconductor chip CP and the portion P1 of the groove portion TR of the die pad DP.

In the case of the present modification, since the convex portion CV is not provided, the value of the distance DCD2 illustrated in FIG. 14 may be smaller than the value of the average particle diameter DMRf of the filler particles MRf. Therefore, in the step of forming the sealing body MR, it is necessary to take a measure for ensuring that the filler particle MRf (in particular, the filler particle MRf having a size close to the average particle diameter DMRf) is easily supplied to the region DR4 illustrated in FIG. 12.

Thus, in the case of the present modification, the value of the distance DCD1 illustrated in FIG. 14 is increased by providing the groove portion TR in the region DR4 illustrated in FIG. 12. The value of the distance DCD1 is, for example, larger than the value of the average particle diameter DMRf of the plurality of filler particles MRf included in the sealing body MR. Note that, in the case of the present modification, the bottom surface TRb (see FIG. 14) of the groove portion TR and the upper surface DPt of the die pad DP at the position where the groove portion TR is not provided are different in height from each other. In the present modification, the bottom surface TRb and a side surface TRs of the groove portion TR are a part of the upper surface DPt of the die pad DP. In other words, the bottom surface TRb and the side surface TRs of the groove portion TR are included in the upper surface DPt of the die pad DP.

In addition, as illustrated in FIG. 14, the groove portion TR includes a portion P1 located at a position overlapping the semiconductor chip CP (that is, a portion including a surface facing the surface CPb of the semiconductor chip CP), and a portion P2 located at a position not overlapping the semiconductor chip CP. In addition, in the example illustrated in FIG. 14, the portion P2 is located closer to the peripheral edge portion DPP than the portion P1. In other words, as illustrated in FIGS. 12 and 13, each of the plurality of groove portions TR is disposed so as to straddle the outer edge of the chip mounting region DBR in plan view. Therefore, in the step of forming the sealing body MR, the filler particle MRf is easily supplied from the gap between the semiconductor chip CP and the groove portion TR.

Here, in each of the plurality of connecting portions CNP, a direction away from the center of the die pad is defined as an extending direction, and a direction orthogonal to the above extending direction is defined as a width direction. In the case of the present modification, each of the groove portions TR illustrated in FIG. 13 is disposed so as to penetrate the connecting portion CNP in the width direction. Specifically, as illustrated in FIG. 15, the connecting portion CNP has one side surface CNPs1 and a side surface CNPs2 opposite to the side surface CNPs1. One end of the groove portion TR intersects the side surface CNPs1 of the connecting portion CNP. The other end of the groove portion TR intersects the side surface CNPs2 of the connecting portion CNP. In this case, as illustrated in FIG. 15, an opening portion allowing the plurality of filler particles MRf to be supplied therethrough is formed between the semiconductor chip CP and the die pad DP3 in the region DR4 (see FIG. 12) of the die pad DP. Therefore, the filler particles MRf can be reliably supplied between the semiconductor chip CP and the die pad DP3.

Note that, as a further modification of the present modification, the groove portion TR may not reach any one or both of the side surface CNPs1 and the side surface CNPs2 of the connecting portion CNP and terminate halfway through the connecting portion CNP. In other words, the groove portion TR may have a recessed shape surrounded by a wall. Even in this case, since the opening is formed between the semiconductor chip CP and the portion P2 of the groove portion TR in the cross section illustrated in FIG. 14, the filler particle MRf can be supplied between the semiconductor chip CP and the groove portion TR.

Conversely, as another modification of the present modification, when each of the groove portions TR illustrated in FIG. 13 is disposed so as to penetrate the connecting portion CNP in the width direction as described with reference to FIG. 15, the portion P2 illustrated in FIG. 14 may not be provided. In this case, since the groove portion terminates at a portion corresponding to the portion P1 in FIG. 14, the filler particle MRf (see FIG. 14) is less likely to be supplied from the direction orthogonal to line E-E illustrated in FIG. 13 (extending direction of the connecting portion CNP). However, since the cross-sectional structure illustrated in FIG. 15 is provided, as a result, the filler particle MRf can be supplied between the groove portion TR and the semiconductor chip CP.

Incidentally, the value of the depth of the groove portion TR defined as the difference between the distance DCD2 and the distance DCD1 illustrated in FIG. 14 is preferably as follows. When the depth of the groove portion TR is equal to or greater than the value of the average particle diameter DMRf of the plurality of filler particles MRf, it is preferable in that a space for disposing the filler particle MRf can be secured even if the value of the distance DCD2 is, for example, a value close to zero. However, in reality, it is not probable that the value of the distance DCD2 is zero, and about several microns is secured. Therefore, the depth of the groove portion TR is preferably such that the value of the distance DCD1 illustrated in FIG. 14 is larger than the value of the average particle diameter DMRf of the plurality of filler particles MRf. Even when the value of the distance DCD1 is larger than the value of the average particle diameter DMRf of the plurality of filler particles MRf, the depth of the groove portion TR may be smaller than the value of the average particle diameter DMRf of the plurality of filler particles MRf.

For example, when the value of the average particle diameter DMRf of the plurality of filler particles MRf is 30 μm, the depth of the groove portion TR is preferably 25 μm or more, particularly preferably 30 μm or more.

As illustrated in FIG. 14, in the case of the present modification, the groove portion TR further includes a portion P3 located between the portion P1 and the central portion DCP and covered with the die bond material DB. In other words, a part of the groove portion TR is covered with the die bond material DB.

Although not illustrated, when the die bond material DB terminates at a position not reaching the groove portion TR, a region where the distance between the semiconductor chip CP and the die pad DP is the distance DCD2 illustrated in FIG. 14 and the die pad DP and the semiconductor chip CP face each other without the die bond material DB interposed therebetween may be generated between the die bond material DB and the groove portion TR. In this region, the filler particle MRf is not supplied, and thus the cavity that causes the above-described peeling may be generated.

As illustrated in FIG. 14, when the groove portion TR includes the portion P3 covered with the die bond material DB, the region that causes the generation of the above-described cavity is not generated. Therefore, from the viewpoint of reducing the possibility of cavity generation, it is preferable that the groove portion TR includes the portion P3 as in the present modification.

As illustrated in FIG. 13, the plurality of connecting portions CNP of the present modification includes the connecting portion CNP1 extending from the central portion DCP toward the peripheral edge portion DPP, and the connecting portion CNP2 disposed on the opposite side of the connecting portion CNP1 across the central portion DCP. The die pad DP3 includes the groove portion TR1 provided in the connecting portion CNP1 and the groove portion TR2 provided in the connecting portion CNP2. The depth of the groove portion TR1 and the depth of the groove portion TR2 are equal to each other. Furthermore, the plurality of connecting portions CNP further includes the connecting portion CNP3 extending from the central portion DCP toward the peripheral edge portion DPP, and the connecting portion CNP4 disposed on the opposite side of the connecting portion CNP3 across the central portion DCP. The die pad DP3 includes the groove portion TR3 provided in the connecting portion CNP3 and the groove portion TR4 provided in the connecting portion CNP4.

As can be seen from a comparison between FIG. 12 and FIG. 13, each of the connecting portion CNP1, the connecting portion CNP2, the connecting portion CNP3, and the connecting portion CNP4 overlaps the region DR4 of the die pad DP. Therefore, by providing the groove portion TR in a portion overlapping the region DR4 in each of the connecting portion CNP1, the connecting portion CNP2, the connecting portion CNP3, and the connecting portion CNP4, the cavity that causes the peeling can be suppressed from being generated in any one of the connecting portion CNP1, the connecting portion CNP2, the connecting portion CNP3, and the connecting portion CNP4.

As illustrated in FIG. 13, the wire bonding region WBR to which the wire BWD (see FIG. 3) is connected is provided on the extension line of the connecting portion CNP1 among the plurality of connecting portions CNP. As illustrated in FIG. 14, since the connecting portion CNP1 is provided with the groove portion TR1, the generation of the cavity that causes the peeling can be suppressed at the groove portion TR. Therefore, it is possible to prevent the peeling from progressing toward the wire bonding region WBR from the cavity.

Similarly, the wire bonding region WBR to which the wire BWD (see FIG. 3) is connected is provided on the extension line of each of the connecting portion CNP2, the connecting portion CNP3, and the connecting portion CNP4. As described above, since the groove portion TR is provided in the portion overlapping the region DR4 in each of the connecting portion CNP2, the connecting portion CNP3, and the connecting portion CNP4, it is possible to prevent the peeling from progressing toward any of the plurality of wire bonding regions WBR.

The die pad DP3 and the semiconductor device PKG4 (see FIG. 14) illustrated in FIGS. 12 to 15 are the same as the die pad DP and the semiconductor device PKG1 described with reference to FIGS. 1 to 7 except for the above-described difference. Therefore, redundant description will be omitted.

### <Modification of Die Pad Shape>

Next, a modification of the shape of the die pad (in particular, the planar shape of the through hole DTH2) will be described. FIGS. 16 and 17 are enlarged plan views illustrating the modification of the die pad illustrated in FIGS. 9 and 10.

In the case of the die pad DP2 illustrated in FIG. 10, the connecting portion CNP1 and the connecting portion CNP2 are disposed along the extending direction of the hung lead HL1 and the hung lead HL2. In addition, the connecting portion CNP3 and the connecting portion CNP4 are disposed along the extending direction of the hung lead HL3 and the hung lead HL4.

In the case of a die pad DP4 illustrated in FIG. 17, the connecting portion CNP1 and the connecting portion CNP2 are disposed along the X direction. In addition, in the case of the die pad DP4, the connecting portion CNP3 and the connecting portion CNP4 are disposed along the Y direction.

In the die pad DP4, the planar shapes of the plurality of through holes DTH2 are quadrangular. In this case, the area of the chip mounting region DBR overlapping any of the plurality of through holes DTH2 is larger than that in the die pad DP2 illustrated in FIG. 10. In other words, when the die pad DP4 is used, the area of a region in close contact with the sealing body MR on the surface CPb of the semiconductor chip CP illustrated in FIG. 2 is larger than that in the die pad DP. The value of the adhesive strength between the sealing body MR and the semiconductor chip CP is larger than the value of the adhesive strength between the sealing body MR and the die pad DP and the value of the adhesive strength between the sealing body MR and the die bond material DB. Therefore, from the viewpoint of improving adhesion between the semiconductor chip CP and the sealing body MR, the die pad DP4 of the present modification is preferable.

Also when, as in the present modification, the plurality of connecting portions CNP is disposed along the X direction or the Y direction, which is inclined by 45 degrees with respect to the extending direction of the hung lead HL, the technique related to the convex portion CV described with reference to FIGS. 5 to 11 and the technique related to the groove portion TR described with reference to FIGS. 12 to 15 can be applied.

That is, in FIGS. 16 and 17, the modification of FIGS. 9 and 10 is described as a representative example, but the layout of the plurality of connecting portions CNP illustrated in FIG. 17 can be applied in combination with the layout of the convex portion CV illustrated in FIG. 6.

The die pad DP4 and a semiconductor device using the die pad DP4 illustrated in FIGS. 16 and 17 are the same as the die pad DP2 and the semiconductor device PKG3 (see FIG. 11) described with reference to FIGS. 9 to 11 except for the above-described difference. Therefore, redundant description will be omitted.

### <Method of Manufacturing Semiconductor Device>

Next, a method of manufacturing the semiconductor device described with reference to FIGS. 1 to 17 will be described. Hereinafter, a method of manufacturing the semiconductor device PKG1 illustrated in FIG. 7 will be taken as a representative example, and only differences from the representative example will be described regarding a method of manufacturing the semiconductor device PKG3 illustrated in FIG. 11 and a method of manufacturing the semiconductor device PKG4 illustrated in FIG. 14. Note that description will be omitted regarding a method of manufacturing the semiconductor device using the die pad DP4 illustrated in FIGS. 16 and 17 because the method is the same as the method of manufacturing each semiconductor device described above.

FIG. 18 is an explanatory diagram illustrating a flow of an assembly step of any of the plurality of semiconductor devices described with reference to FIGS. 1 to 17. Although FIG. 18 illustrates main steps of the manufacturing process of the semiconductor device PKG1 illustrated in FIG. 1, various modifications can be applied in addition to the assembly flow illustrated in FIG. 18. For example, although a marking step of forming a product identification mark on the sealing body MR (see FIG. 1) is not illustrated in FIG. 18, the step can be added between the sealing step and a plating step. In addition, for example, although an inspection step is not illustrated in FIG. 18, the inspection step may be added, for example, after a dicing step.

### <Base Material Preparation Step>

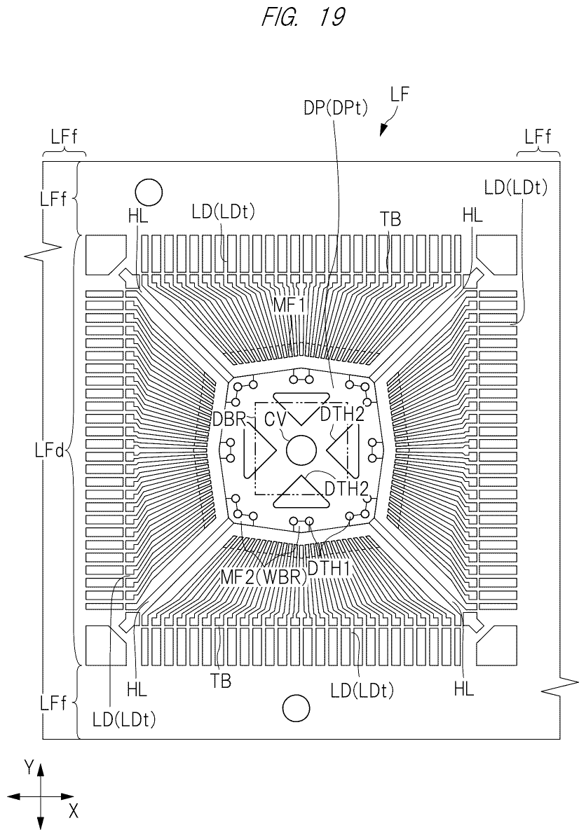

In a base material preparation step illustrated in FIG. 18, a lead frame LF illustrated in FIG. 19 is prepared. FIG. 19 is an enlarged plan view illustrating a lead frame prepared in the base material preparation step illustrated in FIG. 18.

The lead frame LF prepared in this step includes a plurality of device formation portions LFd inside a frame portion LFf. Note that, although the lead frame LF is a base material including the plurality of device formation portions LFd, one of the plurality of device formation portions LFd is illustrated in an enlarged manner in FIG. 19 for easy viewing. The lead frame LF is made of metal, and, in the present embodiment, is made of, for example, copper (Cu) or a copper alloy.

In addition, as illustrated in FIG. 19, the die pad DP that is the chip mounting portion is formed at the central portion of the device formation portion LFd. Each of the plurality of hung leads HL is connected to the die pad DP, and is disposed so as to extend toward the corner portion of the device formation portion LFd. That is, the die pad DP is supported by the hung lead HL, and is supported by the frame portion LFf of the lead frame LF via the hung lead HL.

In addition, the plurality of leads LD is formed between the plurality of hung leads HL around the die pad DP. Each of the plurality of leads LD is connected to the frame portion LFf.

In addition, the plurality of leads LD is connected to each other via a tie bar TB. The tie bar TB has a function as a connecting member that connects the plurality of leads LD and a function as a dam member that suppresses resin leakage in the sealing step illustrated in FIG. 18. The tie bar TB is connected to the plurality of leads LD and the frame portion LFf of the lead frame LF. In addition, one end of the plurality of leads LD is connected to the frame portion LFf of the lead frame LF. Thus, until a lead cutting step illustrated in FIG. 18, each of the plurality of leads LD is supported by the frame portion LFf of the lead frame LF.

The lead frame LF prepared in this step has the structure of the die pad DP described with reference to FIGS. 4 to 7, the structure of the die pad DP2 described with reference to FIGS. 9 to 11, the structure of the die pad DP3 described with reference to FIGS. 12 to 15, or the structure of the die pad DP4 described with reference to FIGS. 16 and 17. In the example illustrated in FIG. 19, the lead frame LF has the structure of the die pad DP described with reference to FIGS. 4 to 7.

That is, the die pad DP includes the upper surface DPt, and the upper surface DPt includes the region DR1 and the region DR2 surrounding the periphery of the region DR1 in plan view. As illustrated in FIG. 7, in the die bonding step illustrated in FIG. 18, the region DR1 includes the region DR3 having the surface facing the surface CPb of the semiconductor chip CP across the die bond material DB, and the region DR4 having the surface facing the surface CPb of the semiconductor chip CP via the sealing body MR instead of the die bond material DB. The die pad DP includes the convex portion CV provided in the region DR3 and protruding upward from the flat surface (reference surface) including the upper surface DPt.

In addition, the metal film MF1 is formed on each of the upper surfaces LDt of the distal ends of the plurality of leads LD. The metal film MF2 partially covering the upper surface DPt of the die pad DP is formed in the plurality of wire bonding regions WBR of the die pad DP. In addition, the through hole DTH1 penetrating from one of the upper surface DPt and the lower surface DPb (see FIG. 7) of the die pad DP to the other is formed on the die pad DP. The through hole DTH1 is formed at the position overlapping the metal film MF2. In the example illustrated in FIG. 19, the die pad DP includes the wire bonding regions WBR at eight locations, and each of the wire bonding regions WBR is covered with the metal film MF2. The plurality of through holes DTH1 are formed on each of the wire bonding regions WBR. In addition, the die pad DP includes the plurality of through holes DTH2 penetrating through the die pad DP in the thickness direction (Z direction illustrated in FIG. 2). Each of the plurality of through holes DTH2 is located at the position overlapping a part of the chip mounting region DBR that is a region where the semiconductor chip is to be mounted in the die bonding step illustrated in FIG. 18.

The lead frame illustrated in FIG. 19 is manufactured as follows, for example. In the base material preparation step, first, a metal plate that is a base of the lead frame LF is prepared (metal plate preparation step). The metal plate is made of metal containing copper as a main component. The metal plate is formed by rolling a metal material.

Next, the base material preparation step includes a pattern formation step of forming a metal pattern as illustrated in FIG. 19 by processing the metal plate after the metal plate preparation step. In this pattern formation step, cutting is performed to cut the plurality of leads LD, the die pad DP, and the like into the shape illustrated in FIG. 19. In addition, in the pattern formation step, drilling is performed to form the plurality of through holes DTH1 on the die pad DP. For cutting, for example, a method that performs pressing in a state where a mold is sandwiched between a punch and a die, or a method that removes an unnecessary portion by etching can be used. In addition, in drilling for forming the through hole DTH1 and the through hole DTH2, the above-described method that uses a mold to perform pressing and a method that cuts a metal plate using a drill may be used.

Furthermore, the convex portion CV illustrated in FIG. 19 is formed by pressing using a mold, for example. In this case, as illustrated with reference to FIG. 7, the depressed portion DEP is formed on the lower surface DPb of the die pad DP on the opposite side of the convex portion CV.

In the case of the die pad DP3 described with reference to FIGS. 12 to 15, the plurality of groove portions TR is formed in the pattern formation step. The groove portion TR can be formed by removing a part of the lead frame LF (see FIG. 19) by, for example, etching or laser irradiation.

In addition, the base material preparation step includes a metal film formation step of forming the metal film MF2 on the upper surface DPt of the die pad DP after the pattern formation step. In the metal film formation step, the metal film MF1 is also formed in addition to the plurality of metal films MF2 illustrated in FIG. 19.

In addition, the base material preparation step includes a bending step of bending a part (offset portion) of the hung lead and offsetting the position of the die pad DP. This bending step can be performed after the above-described pattern formation step or after the metal film formation step.

### <Die Bonding Step>

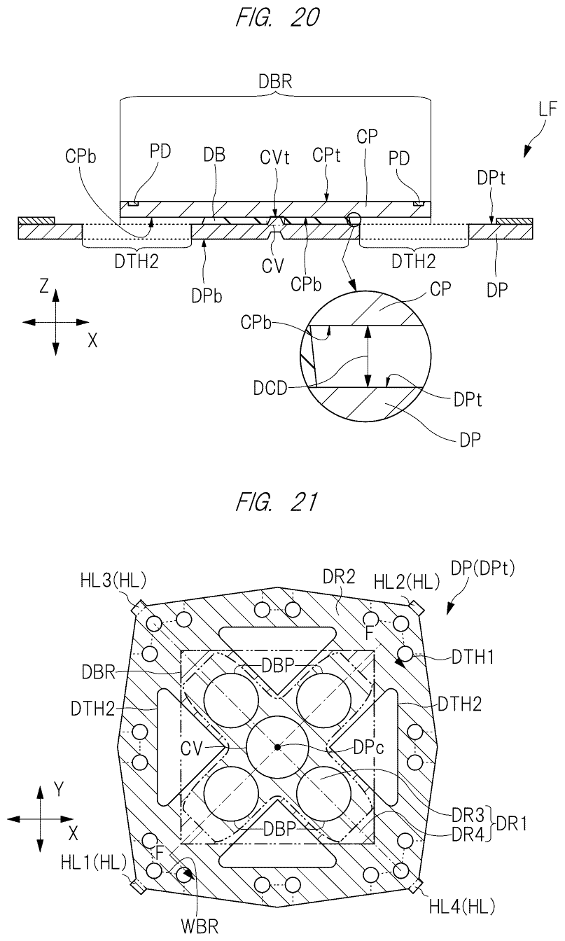

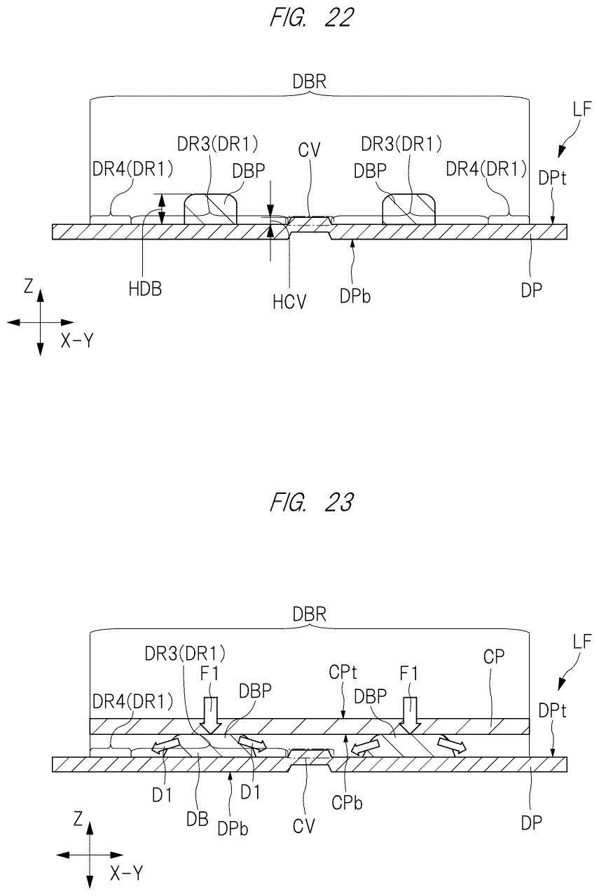

Next, in the die bonding step (semiconductor chip mounting step) illustrated in FIG. 18, the semiconductor chip CP is mounted on the die pad DP as illustrated in FIG. 20. FIG. 20 is an enlarged cross-sectional view illustrating a state where the semiconductor chip is mounted on the die pad of the lead frame illustrated in FIG. 19. FIG. 21 is an enlarged plan view illustrating a state where a paste-like die bond material DBP is applied onto the die pad in the die bonding step. FIG. 22 is an enlarged cross-sectional view taken along line F-F in FIG. 21. FIG. 23 is an enlarged cross-sectional view illustrating a state where the semiconductor chip is pressed against the die pad illustrated in FIG. 22 to spread the paste-like die bond material.

As illustrated in FIG. 20, the die bonding step includes a chip preparation step of preparing the semiconductor chip CP including the surface CPb, the surface CPt located on the opposite side of the surface CPb, and the plurality of electrode pads PD arrayed on the surface CPt. The die bonding step includes a chip mounting step of mounting the semiconductor chip CP on the region DR1 (see FIG. 21) of the die pad DP via the die bond material DB such that the surface CPb of the semiconductor chip CP faces the upper surface DPt of the die pad DP. Note that the above-described chip preparation step is the step of conveying the semiconductor chip CP to be mounted in the chip mounting step to a place where the chip mounting step is performed. The step of manufacturing the semiconductor chip CP is performed in advance before the die bonding step is performed.

For example, as described with reference to FIGS. 5 to 7, the upper surface DPt of the die pad DP after the die bonding step includes the region DR3 having the surface facing the surface CPb of the semiconductor chip CP with the die bond material DB interposed therebetween, and the region DR4 having the surface facing the surface CPb of the semiconductor chip CP without the die bond material DB interposed therebetween.

As illustrated in FIGS. 21 and 22, the die bonding step includes a die bond material application step of applying the die bond material DBP to a plurality of positions in the region DR3 (see FIG. 21) of the die pad DP. The die bond material DBP illustrated in FIGS. 21 and 22 is a paste-like material before being cured.

As describes above, the die bond material DB illustrated in FIG. 2 is an adhesive material used when the semiconductor chip CP is die-bonded, and is, for example, a resin adhesive material containing metal particles made of silver or the like in an epoxy-based thermosetting resin, or a metal bond material such as a solder material. The die bond material DBP is, for example, a conductive paste (so-called silver paste) containing an epoxy resin before being cured and a plurality of silver particles. Alternatively, the die bond material DBP is a conductive paste (so-called solder paste) containing a solvent and a solder component dissolved in the solvent.

As illustrated in FIGS. 21 and 22, in the die bond material application step, the die bond material DBP is applied to the region DR1 (specifically, the region DR3). The die bond material DBP is not applied onto the convex portion CV but applied around the convex portion CV. Considering the spreadability of the die bond material DBP in a die bond material spreading step to be described later, it is preferable that the die bond material DBP is applied to at least both sides of the convex portion CV in the die bond material application step.

When the die pad DP2 illustrated in FIGS. 9 and 11 is used, it is preferable that the die bond material DBP is applied to both sides of each of the plurality of convex portions CV. In addition, when the die pad DP2 is used, the die bond material DBP (see FIG. 21) may be applied to the center DPc of the upper surface DPt of the die pad DP2 illustrated in FIG. 10 in addition to both sides of each of the plurality of convex portions CV.

When the die pad DP3 illustrated in FIGS. 12 and 13 is used, the die bond material DBP is applied to a plurality of any portions of the region DR3 illustrated in FIG. 12 in the die bond material application step. For example, the die bond material DBP is applied to a total of 5 portions including the center DPc illustrated in FIG. 12 and four portions around the center DPc. From the viewpoint of preventing the die bond material DBP from spreading to the wire bonding region WBR, the die bond material DBP is not applied to the region DR4 in this step. The same applies to when the die pad DP2 illustrated in FIG. 9 is used, when the die pad DP3 illustrated in FIG. 12 is used, and when the die pad DP4 illustrated in FIG. 16 is used.

As a modification of the present embodiment, there is a method that applies the die bond material DBP onto the convex portion CV in the die bond material application step. However, when the die bond material DBP is applied onto the convex portion CV, a gap may be generated between the side surface of the convex portion CV and the die bond material DBP in the die bond material spreading step. Therefore, from the viewpoint of preventing the generation of the gap, it is preferable that the die bond material DBP is applied to a place different from the convex portion. In the example illustrated in FIG. 21, since the convex portion CV is formed at the center DPc of the upper surface DPt of the die pad DP, the die bond material DBP is not applied to the center DPC.

As illustrated in FIG. 22, a height HDB of the applied die bond material DBP is preferably higher than the protrusion height HCV of the convex portion CV. When the position of the upper surface DPt of the die pad DP in the region DR3 is set as a reference surface, the height HDB is defined by the distance (shortest distance) from the top of the die bond material DBP to the reference surface. As illustrated in FIG. 22, since the height HDB of the applied die bond material DBP is higher than the protrusion height HCV of the convex portion CV, the surface CPb of the semiconductor chip CP can be brought into contact with the die bond material DBP before being brought into contact with the convex portion CV in the die bond material spreading step illustrated in FIG. 23.

As illustrated in FIG. 23, the die bonding step includes the die bond material spreading step of pressing the semiconductor chip CP against the die pad DP and spreading the die bond material DBP within the region DR3.

In the die bond material spreading step, as schematically illustrated by a white arrow in FIG. 23, a pressing force F1 is applied to the die bond material DBP in a state where the surface CPb of the semiconductor chip CP and the die bond material DBP are in contact with each other. Since each of the plurality of die bond materials DBP is sandwiched between the semiconductor chip CP and the die pad DP, the die bond material DBP is spread in a spreading direction D1.

When the semiconductor chip CP is further pressed against the die pad DP from the state illustrated in FIG. 23, the surface CPb of the semiconductor chip CP and the top surface CVt of the convex portion CV come into contact with each other as illustrated in FIG. 20. Therefore, when the die bond material spreading step has been completed, the distance (that is, the thickness of the die bond material DBP) between the surface CPb of the semiconductor chip CP and the upper surface DPt of the die pad DP in the region DR3 is defined by the protrusion height HCV of the convex portion CV (see FIG. 20).

In the die bond material spreading step, when a part of the die bond material DBP rides on the top surface CVt (see FIG. 20) of the convex portion CV, a part of the die bond material DBP may remain on the convex portion CV and the semiconductor chip CP. However, even if a part of the die bond material DBP rides on the top surface CVt of the convex portion CV, most of the part of the die bond material DBP that rides on the top surface CVt is pushed out to the periphery of the convex portion CV by the pressing force F1 illustrated in FIG. 23.

Therefore, when this step has been completed, as illustrated in FIG. 20, the surface CPb of the semiconductor chip CP and the top surface CVt of the convex portion CV can be regarded as being substantially in contact with each other.

Although not illustrated, the die bonding step includes a die bond material curing step of curing the die bond material DBP after the die bond material spreading step. When the die bond material curing step is completed, the cured die bond material DB is obtained as illustrated in FIG. 20.

When the die bond material DBP is a resin adhesive material containing metal particles made of silver or the like in an epoxy-based thermosetting resin, the die bond material DBP (see FIG. 22) is heated (by cure baking) until the curing temperature of the thermosetting resin or higher is reached in the die bond material curing step. When the die bond material DBP is a solder paste, the die bond material DBP (see FIG. 22) is heated to a temperature equal to or higher than the melting point of the solder component to volatilize the solvent, and then cooled. This process is called a reflow process.

Incidentally, in the case of the method of manufacturing the semiconductor device using the die pad DP2 described with reference to FIGS. 9 to 11, the surface CPb of the semiconductor chip CP illustrated in FIG. 11 comes into contact with the top surface CVt of each of the plurality of convex portions CV in the die bonding step. As described above, the value of the protrusion height HCV of the convex portion CV1 illustrated in FIG. 11 is the same as each value of the protrusion height HCV of the convex portion CV2, the protrusion height HCV of the convex portion CV3, and the protrusion height HCV of the convex portion CV4. Therefore, the surface CPb of the semiconductor chip CP and the upper surface DPt of the die pad DP can be made parallel to each other by pressing the semiconductor chip CP until the surface CPb comes into contact with each of the plurality of convex portions CV.

When the surface CPb of the semiconductor chip CP and the upper surface DPt of the die pad DP are parallel to each other, the value of the distance DCD in the region DR4 illustrated in FIG. 11 can be brought close to the design value (in other words, a value defined by the protrusion height HCV of each of the plurality of convex portions CV). As a result, the generation of the cavity that causes the above-described peeling can be suppressed at any place of the region DR4 illustrated in FIG. 9.

In the case of the method of manufacturing the semiconductor device using the die pad DP3 described with reference to FIGS. 12 to 15, the convex portion CV illustrated in FIGS. 20 to 23 is not provided. For this reason, in the die bonding step, the end position of the die bond material spreading step of pressing the semiconductor chip CP against the die pad DP (the value of the distance DCD2 illustrated in FIG. 14 when the die bond material spreading step has ended) needs to be controlled. In addition, control needs to be performed to ensure that the surface CPb of the semiconductor chip CP and the upper surface DPt of the die pad DP are parallel to each other when the die bond material spreading step has been completed.

However, as described above, the die pad DP3 includes the groove portion TR formed on each of the plurality of connecting portions CNP. Therefore, even when the value of the distance DCD2 is smaller than the value of the average particle diameter DMRf of the filler particles MRf illustrated in FIG. 14, the value of the distance DCD1 can be set to a value larger than the value of the average particle diameter DMRf of the filler particles MRf.

### <Wire Bonding Step>

Next, in the wire bonding step illustrated in FIG. 18, as illustrated in FIGS. 2 and 3, the plurality of electrode pads PD formed on the surface CPt of the semiconductor chip CP and the die pad DP or the plurality of leads LD is electrically connected to each other via the plurality of wires (conductive members) BW.

The plurality of wires BW illustrated in FIG. 3 includes the wire BWC that electrically connects the electrode pad PD of the semiconductor chip CP and the plurality of leads LD. One end of the wire BWC is bonded to the electrode pad PD of the semiconductor chip CP, and the other end is bonded to the wire bonding region of the distal end of the lead LD (a portion covered with the metal film MF1 illustrated in FIG. 4). In addition, the plurality of wires BW includes the wire BWD that electrically connects the electrode pad PD of the semiconductor chip CP and the die pad DP, or the die pad DP and the lead LD. At least one end of the wire BWD is bonded to the wire bonding region WBR of the die pad DP (a portion covered with the metal film MF2 illustrated in FIG. 4).

In other words, the wire bonding step includes a step of connecting the wire BWD to the region DR2 of the die pad DP illustrated in FIG. 5. Although redundant description is omitted, the same applies to the case of the die pad DP2 illustrated in FIG. 9, the case of the die pad DP3 illustrated in FIG. 12, and the case of the die pad DP4 illustrated in FIG. 16.

There are various modifications of the bonding method of the wire BW, and for example, a bonding method is used that applies heat and ultrasonic waves to the bonding portion of the wire BW to crimp the bonding portion to the bonded portion (the electrode pad PD, metal film MF1, or metal film MF2) using a bonding tool (for example, a capillary).

### <Sealing Step>

Next, in the sealing step illustrated in FIG. 18, the semiconductor chip CP, the plurality of wires BW, and the die pad DP illustrated in FIG. 2 are sealed with a resin to form the sealing body MR. The sealing body MR illustrated in FIG. 7, FIG. 11, or FIG. 14 is an insulating material containing the plurality of filler particles MRf and the resin component MRr.

In this step, for example, a resin is supplied into a space formed by a cavity (not illustrated) in a state where the lead frame LF is disposed in a forming mold including the cavity, and then the above resin is cured to form the sealing body (sealing portion) MR. Such a method of forming the sealing body MR is called a transfer molding method.

The cavity that causes the above-described peeling is generated in the sealing step when there is a variation in the shrinkage rate of the sealing body MR in the heating step (cure baking step) for curing the sealing body MR.

In the case of the present embodiment, as described above, a part of the plurality of filler particles MRf is supplied between the surface CPb of the semiconductor chip CP and the region DR4 of the die pad DP in the sealing step.

Thus, the variation in shrinkage rate in the sealing body MR that causes the generation of the cavity can be suppressed. Since the generation of the cavity can be suppressed by suppressing the variation in shrinkage rate in the sealing body MR, as a result, the progress of the above-described peeling can be suppressed.

### <Plating Step>

Next, in the plating step illustrated in FIG. 18, the metal film MC is formed by plating on the exposed surfaces of the plurality of leads LD illustrated in FIG. 2. The metal film MC formed in this step is formed to improve the wettability of the solder material used as a bond material when the semiconductor device PKG1 is mounted on the mounting substrate (not illustrated).

In this step, it is preferable that the metal film MC made of solder is formed on the exposed surface of the lead LD. In addition, as a method of forming g the metal film MC, electroplating can be applied that deposits ionized metal ions on the exposed surface of the lead LD. Electroplating is preferable in that the film quality of the metal film MC can be easily controlled by controlling a current when the metal film MC is formed. In addition, electroplating is preferable in that the formation time of the metal film MC can be shortened.

### <Lead Cutting Step>

Next, in the lead cutting step illustrated in FIG. 18, the outer lead portion OLD of each of the plurality of leads LD illustrated in FIG. 3 is cut to separate each of the plurality of leads LD from the lead frame LF illustrated in FIG. 19.

In addition, in the present embodiment, after the lead LD is cut, the plurality of leads LD are formed by performing bending as illustrated in FIG. 2.

In this step, the tie bar TB (see FIG. 19) connecting the plurality of leads LD illustrated in FIG. 19 is cut. Further, each of the plurality of leads LD is separated from the frame portion LFf. As a result, the plurality of leads LD become independent members separated from each other. In addition, after the plurality of leads LD is separated, the sealing body MR and the plurality of leads LD are supported by the frame portion LFf via the hung lead HL (see FIG. 19).

The plurality of leads LD and the tie bar TB are cut by pressing using a cutting mold. In addition, the plurality of cut leads LD can be formed as illustrated in FIG. 2, for example, by performing bending on the outer lead portions OLD of the plurality of leads LD by pressing using a forming mold (not illustrated).

### <Dicing Step>

Next, in the dicing step illustrated in FIG. 18, each of the plurality of hung leads HL illustrated in FIG. 19 is cut to separate the semiconductor package at each of the device formation portions LFd.

In this step, the plurality of hung leads HL illustrated in FIG. 19 is cut to obtain the semiconductor package (specifically, an inspection body before the inspection step). For the cutting method of example, the hung lead can be cut by pressing using the cutting mold (not illustrated), as in the above lead formation step.

After this step, necessary inspections and tests such as an appearance inspection and an electrical test are performed, and a product that has passed these inspections and tests becomes the semiconductor device PKG1 as a finished product illustrated in FIG. 1, the semiconductor device PKG3 illustrated in FIG. 11, or the semiconductor device PKG4 illustrated in FIG. 14.

In the foregoing, the invention made by the inventors of the present application has been concretely described on the basis of the embodiments. However, it is needless to say that the present invention is not limited to the foregoing embodiments, and various modifications and alterations can be made within the scope of the present invention.

What is claimed is:

1. A semiconductor device comprising:
a die pad including a first surface having a first region and a second region surrounding the first region in plan view;
a semiconductor chip including a second surface facing the first surface, a third surface opposite the second surface, and a plurality of electrodes arrayed on the third surface, the semiconductor chip being mounted in the first region of the die pad via a die bond material;
a plurality of leads arrayed around the die pad in plan view;
a plurality of wires; and
a sealing body that seals the semiconductor chip, the plurality of wires, and the first surface of the die pad,
wherein the plurality of wires includes a first wire connected to the second region of the die pad,
wherein the first region of the die pad includes:
a third region having a surface facing the second surface of the semiconductor chip via the die bond material; and
a fourth region having a surface facing the second surface of the semiconductor chip via the sealing body,
wherein the die pad includes a first convex portion provided in the third region and protruding from a flat surface including the first surface toward the semiconductor chip,
wherein the sealing body includes a plurality of filler particles, and
wherein a part of the plurality of filler particles is interposed between the second surface of the semiconductor chip and the first surface, which is located in the fourth region, of the die pad.

2. The semiconductor device according to claim 1,
wherein the die pad includes a plurality of through holes penetrating through the die pad in a thickness direction, and
wherein the second surface of the semiconductor chip is in contact with the sealing body at a position where each of the plurality of through holes is formed.

3. The semiconductor device according to claim 2,
wherein the first convex portion faces a center of the second surface of the semiconductor chip.

4. The semiconductor device according to claim 2,
wherein the die pad includes:
a central portion including a center of the first surface;
a peripheral edge portion included in the second region; and
a plurality of connecting portions disposed between the plurality of through holes in plan view and extending so as to connect the central portion and the peripheral edge portion with each other,
wherein the plurality of connecting portions includes:
a first connecting portion extending from the central portion toward the peripheral edge portion; and
a second connecting portion disposed on an opposite side of the first connecting portion across the central portion, and
wherein the die pad includes:
the first convex portion provided in the third region of the first connecting portion and protruding from the flat surface including the first surface toward the semiconductor chip; and
a second convex portion provided in the third region of the second connecting portion and protruding from the flat surface including the first surface toward the semiconductor chip, a protrusion height of the second convex portion being the same as a protrusion height of the first convex portion.

5. The semiconductor device according to claim 4,
wherein the plurality of connecting portions further includes:
a third connecting portion extending from the central portion toward the peripheral edge portion; and
a fourth connecting portion disposed on an opposite side of the third connecting portion across the central portion, and
wherein the die pad further includes:
a third convex portion provided in the third region of the third connecting portion and protruding from the flat surface including the first surface toward the semiconductor chip, a protrusion height of the third convex portion being the same as a protrusion height of the first convex portion; and
a fourth convex portion provided in the third region of the fourth connecting portion and protruding from the flat surface including the first surface toward the semiconductor chip, a protrusion height of the fourth convex portion being the same as a protrusion height of the first convex portion.

6. The semiconductor device according to claim 4,
wherein a plurality of suspension leads supporting the die pad is connected to the die pad,
wherein each of the first connecting portion and the second connecting portion is disposed on an extension line of a first suspension lead of the plurality of suspension leads, and
wherein a first wire bonding region to which the first wire is connected is provided between the first connecting portion and the first suspension lead.

7. The semiconductor device according to claim 1,
wherein a distance between the first surface of the die pad in the fourth region and the second surface of the semiconductor chip is larger than an average value of particle diameters of the plurality of filler particles.

8. A semiconductor device comprising:
a die pad including a first surface, a plurality of through holes, a central portion including a center of the first surface, a peripheral edge portion at a peripheral edge of the first surface, and a plurality of connecting portions disposed between the plurality of through holes in plan view and extending so as to connect the central portion and the peripheral edge portion with each other;
a semiconductor chip including a second surface facing the first surface, a third surface opposite the second surface, and a plurality of electrodes arrayed on the third surface, the semiconductor chip being mounted in a chip mounting region of the first surface of the die pad via a die bond material;
a plurality of leads arrayed around the die pad in plan view;
a plurality of wires; and
a sealing body that seals the semiconductor chip, the plurality of wires, and the first surface of the die pad,
wherein the plurality of wires includes a first wire connected to the peripheral edge portion of the die pad,
wherein the die pad includes a groove portion formed at each of the plurality of connecting portions,
wherein the groove portion includes:
a first portion exposed from the die bond material and facing the second surface of the semiconductor chip via the sealing body; and
a second portion located at a position not overlapping the semiconductor chip,
wherein a first distance from a bottom surface of the first portion of the groove portion to the second surface of the semiconductor chip is larger than a second distance from a flat surface including the first surface of the central portion to the second surface of the semiconductor chip,
wherein the sealing body includes a plurality of filler particles, and
wherein a part of the plurality of filler particles is interposed between the second surface of the semiconductor chip and the first portion of the groove portion of the die pad.

9. The semiconductor device according to claim 8,
wherein each of the plurality of connecting portions has a first side surface and a second side surface opposite the first side surface,
wherein one end of the groove portion intersects the first side surface, and
wherein an other end of the groove portion intersects the second side surface.

10. The semiconductor device according to claim 9,
wherein the plurality of connecting portions further includes:
a first connecting portion extending from the central portion toward the peripheral edge portion;
a second connecting portion disposed on an opposite side of the first connecting portion across the central portion;
a third connecting portion extending from the central portion toward the peripheral edge portion; and
a fourth connecting portion disposed on an opposite side of the third connecting portion across the central portion, and
wherein the die pad further includes:
a first groove portion provided on the first connecting portion;
a second groove portion provided on the second connecting portion;
a third groove portion provided on the third connecting portion; and
a fourth groove portion provided on the fourth connecting portion.

11. The semiconductor device according to claim 8,
wherein a first wire bonding region to which the first wire is connected is provided on an extension line of the first connecting portion among the plurality of connecting portions.

12. The semiconductor device according to claim 8,
wherein the groove portion further includes a third portion located between the first portion and the central portion and covered with the die bond material.

13. The semiconductor device according to claim 8,
wherein the first distance is larger than an average value of particle diameters of the plurality of filler particles.

14. A method of manufacturing a semiconductor device comprising:
(a) preparing a lead frame including a die pad having a first surface including a first region and a second region surrounding the first region in plan view, and a plurality of leads arrayed on a periphery of the die pad in plan view;
(b) preparing a semiconductor chip including a second surface, a third surface opposite the second surface, and a plurality of electrodes arrayed on the third surface, and mounting the semiconductor chip in the first region of the die pad via a die bond material such that the second surface faces the first surface;
(c) connecting a first wire to the second region of the die pad; and
(d) forming a sealing body that seals the semiconductor chip, the first wire and the die pad with a resin containing a plurality of filler particles,
wherein, in the (b), the first region of the die pad includes:
a third region having a surface facing the second surface of the semiconductor chip via the die bond material; and
a fourth region having a surface facing the second surface of the semiconductor chip without interposing the die bond material between the die pad and the semiconductor chip,
wherein the die pad of the lead frame prepared in the (a) includes a first convex portion provided in the third region and protruding upward from a flat surface including the first surface, and,
wherein, in the (d), a part of the plurality of filler particles is supplied between the second surface of the semiconductor chip and the first surface, which is located in the fourth region, of the die pad.

15. The method of manufacturing a semiconductor device according to claim 14,
wherein the die pad includes a plurality of through holes penetrating through the die pad in a thickness direction, and,
wherein, in the (d), a sealing body is formed such that the second surface of the semiconductor chip is in contact with the sealing body at a position where the plurality of through holes of the die pad and the semiconductor chip overlap each other.

16. The method of manufacturing a semiconductor device according to claim 15,
wherein the (b) includes:
(b1) applying the die bond material to a plurality of locations in the third region of the die pad; and
(b2) pressing the semiconductor chip against the die pad to spread the die bond material within the third region, and
wherein, in the (b2), a distance between the second surface of the semiconductor chip and the first surface of the die pad is defined by a protrusion height of the first convex portion.

17. The method of manufacturing a semiconductor device according to claim 16,
wherein, in the (b1), the die bond material is applied to at least both sides of the first convex portion.

18. The method of manufacturing a semiconductor device according to claim 16,
wherein the die pad includes:
a central portion including a center of the first surface;
a peripheral edge portion included in the second region; and
a plurality of connecting portions disposed between the plurality of through holes in plan view and extending so as to connect the central portion and the peripheral edge portion with each other,
wherein the plurality of connecting portions includes:
a first connecting portion extending from the central portion toward the peripheral edge portion; and
a second connecting portion disposed on an opposite side of the first connecting portion across the central portion, and
wherein the die pad includes:
the first convex portion provided in the third region of the first connecting portion and protruding from the flat surface including the first surface toward the semiconductor chip; and
a second convex portion provided in the third region of the second connecting portion and protruding from the flat surface including the first surface toward the semiconductor chip, a protrusion height of the second convex portion being the same as a protrusion height of the first convex portion.

19. The method of manufacturing a semiconductor device according to claim 18,
wherein the plurality of connecting portions includes:
a third connecting portion extending from the central portion toward the peripheral edge portion; and
a fourth connecting portion disposed on an opposite side of the third connecting portion across the central portion, and
wherein the die pad further includes:
a third convex portion provided in the third region of the third connecting portion and protruding from the flat surface including the first surface toward the semiconductor chip, a protrusion height of the third convex portion being the same as a protrusion height of the first convex portion; and
a fourth convex portion provided in the third region of the fourth connecting portion and protruding from the flat surface including the first surface toward the semiconductor chip, a protrusion height of the fourth convex portion being the same as a protrusion height of the first convex portion.
